(19) United States
(12) Patent Application Publication
(10) Pub. No.: US 2026/0247708 A1
(43) Pub. Date: Aug. 20, 2026

(54) DISPLY PANEL AND DISPLAY APPARATUS

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Quanyong GU, Beijing (CN); Tiaomei ZHANG, Beijing (CN); Ziyang YU, Beijing (CN); Mengqi WANG, Beijing (CN); Wenbo CHEN, Beijing (CN); Pan ZHAO, Beijing (CN); Erjin ZHAO, Beijing (CN); Zhiliang JIANG, Beijing (CN); Ming HU, Beijing (CN)

(21) Appl. No.: 18/992,602

(22) PCT Filed: Jun. 12, 2023
(86) PCT No.: PCT/CN2023/099649

§ 371 Date: Jan. 9, 2025

(51) Int. Cl. H10D 86/40

(52) U.S. Cl. CPC H10D 86/421; H10D 86/441

(57) ABSTRACT

A display panel includes a pixel driving circuit including a second transistor and a driving transistor, a first electrode of the second transistor is connected to a gate of the driving transistor, and the display panel further includes: a base substrate; an auxiliary layer, located on a side of the base substrate and connected to a first signal; and an active layer, located on a side of the auxiliary layer away from the base substrate; and the active layer includes: a second active portion, configured to form a channel region of the second transistor; and a third active portion, configured to form a channel region of the driving transistor; where an orthographic projection of the auxiliary layer on the base substrate covers an orthographic projection of the second active portion on the base substrate and an orthographic projection of the third active portion on the base substrate.

### CROSS REFERENCE TO RELATED APPLICATIONS

The present application is based upon International Application No. PCT/CN 2023/099649, filed on Jun. 12, 2023, the entire contents of which are incorporated herein by reference.

### TECHNICAL FIELD

The present disclosure relates to the field of display technology, and in particular, to a display panel and a display apparatus.

### BACKGROUND

An organic light-emitting diode (OLED) is an active light-emitting display apparatus, and has the advantages of being self-luminous, wide viewing angle, high contrast, low power consumption, extremely high response speed, lightness and thinness, bendability, etc. Currently, the application of the OLED display screen is more and more extensive. In the related art, the OLED display screen has a problem of color shift after the reliability test.

It should be noted that the information disclosed in the above background part is only used to enhance the understanding of the background of the present disclosure, and therefore may include information that does not constitute the related art known to those of ordinary skill in the art.

### SUMMARY

An objective of the present disclosure is to overcome the above-mentioned shortcomings of the related art, and to provide a display panel and a display apparatus.

According to an aspect of the present disclosure, there is provided a display panel; the display panel includes a pixel driving circuit, the pixel driving circuit includes a second transistor and a driving transistor, and a first electrode of the second transistor is connected to a gate of the driving transistor; the display panel further includes: a base substrate; an auxiliary layer, located on a side of the base substrate and connected to a first signal; and an active layer, located on a side of the auxiliary layer away from the base substrate and comprising: a second active portion, configured to form a channel region of the second transistor; and a third active portion, configured to form a channel region of the driving transistor; where an orthographic projection of the auxiliary layer on the base substrate covers an orthographic projection of the second active portion on the base substrate and an orthographic projection of the third active portion on the base substrate.

In some embodiments of the present disclosure, the display panel comprises a plurality of pixel driving circuits distributed in an array along a row direction and a column direction, the auxiliary layer comprises a plurality of auxiliary units distributed in an array along the row direction and the column direction, an auxiliary unit is provided corresponding to a pixel driving circuit, the second active portion comprises a third active sub-portion and a fourth active sub-portion, and the auxiliary unit comprises: a first auxiliary portion, an orthographic projection of the first auxiliary portion on the base substrate covering the orthographic projection of the third active portion on the base substrate; and a second auxiliary portion, an orthographic projection of the second auxiliary portion on the base substrate covering an orthographic projection of the third active sub-portion on the base substrate and an orthographic projection of the fourth active sub-portion on the base substrate, respectively.

In some embodiments of the present disclosure, the active layer further comprises: a tenth active portion, connected between the third active sub-portion and the fourth active sub-portion; wherein the orthographic projection of the second auxiliary portion on the base substrate does not overlap with an orthographic projection of the tenth active portion on the base substrate.

In some embodiments of the present disclosure, the active layer further comprises: a tenth active portion, connected between the third active sub-portion and the fourth active sub-portion; wherein the second auxiliary portion comprises a first auxiliary sub-portion and a second auxiliary sub-portion, an orthographic projection of the first auxiliary sub-portion on the base substrate covers the orthographic projection of the third active sub-portion on the base substrate and the orthographic projection of the fourth active sub-portion on the base substrate, and an orthographic projection of the second auxiliary sub-portion on the base substrate covers an orthographic projection of the tenth active portion on the base substrate.

In some embodiments of the present disclosure, the display panel further comprises: a second conductive layer, located on a side of the active layer away from the auxiliary layer, the second conductive layer comprising a first conductive block, an orthographic projection of the first conductive block on the base substrate being located on the orthographic projection of the tenth active portion on the base substrate; a second source-drain metal layer, located on a side of the second conductive layer away from the base substrate, the second source-drain metal layer comprising a first power line, an orthographic projection of the first power line on the base substrate extending along the column direction, and the first power line being coupled to the first conductive block through a third via hole; wherein the orthographic projection of the second auxiliary sub-portion on the base substrate further covers an orthographic projection of the third via hole on the base substrate.

In some embodiments of the present disclosure, the active layer further comprises a first active portion connected to a side of the second active portion, the first active portion is configured to form a channel region of the first transistor; and, the auxiliary unit further comprises a fourth auxiliary portion connected to the second auxiliary portion, an orthographic projection of the fourth auxiliary portion on the base substrate covers an orthographic projection of the first active portion on the base substrate.

In some embodiments of the present disclosure, the first active portion comprises a first active sub-portion and a second active sub-portion; and the active layer further comprises a ninth active portion connected between the first active sub-portion and the second active sub-portion; wherein the orthographic projection of the fourth auxiliary portion on the base substrate further covers an orthographic projection of the ninth active portion on the base substrate.

In some embodiments of the present disclosure, the pixel driving circuit further comprises a fourth transistor; the active layer further comprises a fourth active portion configured to form a channel region of the fourth transistor; the auxiliary unit further comprises: a third connecting portion, connected between two auxiliary units adjacent in the column direction, an orthographic projection of the third connecting portion on the base substrate extending along the column direction; and a sixth auxiliary portion, connected to the third connecting portion, an orthographic projection of the sixth auxiliary portion on the base substrate extending along the row direction and covering an orthographic projection of the fourth active portion on the base substrate.

In some embodiments of the present disclosure, the auxiliary unit further comprises: a third connecting portion, connected between two auxiliary units adjacent in the column direction, and an orthographic projection of the third connecting portion on the base substrate extending along the column direction; and a first connecting portion, connected to a side of the second auxiliary portion away from the first auxiliary portion in the column direction, wherein in two auxiliary units adjacent in the column direction, a third connecting portion of an auxiliary unit in a previous row is connected to a first connecting portion of an auxiliary unit in a next row, and an orthographic projection of the first connecting portion on the base substrate does not overlap with an orthographic projection of the first active portion on the base substrate.

In some embodiments of the present disclosure, the first active portion comprises a first active sub-portion and a second active sub-portion; and the active layer further comprises a ninth active portion connected between the first active sub-portion and the second active sub-portion; wherein the orthographic projection of the first connecting portion on the base substrate does not overlap with an orthographic projection of the ninth active portion base substrate.

In some embodiments of the present disclosure, the pixel driving circuit further comprises a fourth transistor; the active layer further comprises a fourth active portion, and the fourth active portion is configured to form a channel region of the fourth transistor; and the auxiliary unit further comprises: a third connecting portion, connected between two auxiliary units adjacent in the column direction, and an orthographic projection of the third connecting portion on the base substrate extending along the column direction; and a sixth auxiliary portion, connected to the third connecting portion, and an orthographic projection of the sixth auxiliary portion on the base substrate extending along the row direction and covering an orthographic projection of the fourth active portion on the base substrate.

In some embodiments of the present disclosure, the pixel driving circuit further comprises a first transistor, and a second electrode of the first transistor is connected to the gate of the driving transistor; the active layer further comprises a first active portion connected to a side of the second active portion, and the first active portion is configured to form a channel region of the first transistor; and the auxiliary unit further comprises: a second connecting portion, respectively connected to the first auxiliary portion and the second auxiliary portion, an orthographic projection of the second connecting portion on the base substrate extending along the row direction, and two auxiliary units adjacent in the row direction being connected through the second connecting portion; a third connecting portion, connected between two auxiliary units adjacent in the column direction, and an orthographic projection of the third connecting portion on the base substrate extending along the column direction; and a first connecting portion or a fourth auxiliary portion, connected to a side of the second auxiliary portion in the column direction away from the first auxiliary portion, wherein in two auxiliary units adjacent in the column direction, a third connecting portion of an auxiliary unit in a previous row is connected to a first connecting portion or a fourth auxiliary portion of an auxiliary unit in a next row, wherein an orthographic projection of the first connecting portion on the base substrate does not overlap with an orthographic projection of the first active portion on the base substrate, and an orthographic projection of the fourth auxiliary portion on the base substrate covers the orthographic projection of the first active portion on the base substrate. In some embodiments of the present disclosure, the display panel further comprises a first source-drain metal layer and/or a second source-drain metal layer located on a side of the active layer away from the base substrate, and the first source-drain metal layer and/or the second source-drain metal layer comprises a second power line and/or a first power line, an orthographic projection of the second power line and/or the first power line extends along the column direction, and in a non-display region of the display panel, the second power line and/or the first power line is connected to the auxiliary layer through a via hole.

In some embodiments of the present disclosure, the display panel further comprises: a second conductive layer, located on a side of the active layer away from the base substrate, the second conductive layer comprising a first initialization signal line and a second initialization signal line, an orthographic projection of the first initialization signal line on the base substrate extending along the row direction, an orthographic projection of the second initialization signal line on the base substrate extending along the row direction; and a first source-drain metal layer, located on a side of the second conductive layer away from the base substrate, the first source-drain metal layer comprising a third initialization signal line and/or a fourth initialization signal line, an orthographic projection of the third initialization signal line on the base substrate extending along the column direction, the third initialization signal line being connected to the first initialization signal line through a first via hole, an orthographic projection of the fourth initialization signal line on the base substrate extending along the column direction, and the fourth initialization signal line being connected to the second initialization signal line through a second via hole.

In some embodiments of the present disclosure, the display panel comprises a first pixel column and a second pixel column that are sequentially and alternately distributed in the row direction; the orthographic projection of the third initialization signal line on the base substrate is at least partially located in a region where the second pixel column is located, the orthographic projection of the fourth initialization signal line on the base substrate is located in a region where the first pixel column is located, and both the first via hole and the second via hole are located in the first pixel column.

In some embodiments of the present disclosure, the pixel driving circuit further comprises a storage capacitor, a first electrode of the storage capacitor is connected to the gate of the driving transistor, and a second electrode of the storage capacitor is connected to a second power end; and the display panel further comprises: a first conductive layer, located on a side of the active layer away from the base substrate, the first conductive layer comprising a second conductive block, an orthographic projection of the second conductive block on the base substrate covering the orthographic projection of the third active portion on the base substrate, and the second conductive block being configured to form the first electrode of the storage capacitor; a second conductive layer, located on a side of the first conductive layer away from the base substrate, the second conductive layer comprising a third conductive block and a first conductive block, an orthographic projection of the third conductive block on the base substrate being located on the orthographic projection of the second conductive block on the base substrate, the third conductive block being configured to form the second electrode of the storage capacitor, an orthographic projection of the first conductive block on the base substrate being located on the orthographic projection of the tenth active portion on the base substrate; and a first source-drain metal layer, located on a side of the second conductive layer away from the base substrate, the first source-drain metal layer comprising a first power transfer line and a second power transfer line, the first power transfer line being connected to the third conductive block respectively through a via hole and further connected to a first conductive block in an adjacent pixel driving circuit through a via hole, the second power transfer line being connected to the third conductive block respectively through a via hole, and an extension length of an orthographic projection of the second power transfer line on the base substrate along the column direction being greater than an extension length of an orthographic projection of the first power transfer line on the base substrate along the column direction.

In some embodiments of the present disclosure, the first power transfer line comprises a first transfer portion, a second transfer portion and a third transfer portion, both an orthographic projection of the first transfer portion on the base substrate and an orthographic projection of the third transfer portion on the base substrate extend along the column direction, an orthographic projection of the second transfer portion on the base substrate extends along the row direction, and the first transfer portion and the third transfer portion are connected through the second transfer portion; and the first transfer portion is connected to the third conductive block and the first power line respectively through a via hole, and the third transfer portion is located in another pixel driving circuit adjacent in the row direction and connected to the first conductive block through a via hole.

In some embodiments of the present disclosure, the auxiliary unit further comprises a second connecting portion connected to the first auxiliary portion and the second auxiliary portion respectively, an orthographic projection of the second connecting portion on the base substrate extends along the row direction, and two auxiliary units adjacent in the row direction are connected through the second connecting portion; wherein an orthographic projection of the second transfer portion on the base substrate partially overlaps with an orthographic projection of the second connecting portion on the base substrate.

In some embodiments of the present disclosure, the first conductive layer further comprises a gate signal line, the gate signal line comprises a main extension portion and an additional portion, an orthographic projection of the main extension portion on the base substrate extends along the row direction and covers the orthographic projection of the third active sub-portion on the base substrate, an orthographic projection of the additional portion on the base substrate extends along the column direction and covers the orthographic projection of the fourth active sub-portion on the base substrate, and a partial structure of the gate signal line is configured to form a gate of the second transistor; the second conductive layer further comprises a first initialization signal line, and an orthographic projection of the first initialization signal line on the base substrate extends along the row direction; and the first source-drain metal layer further comprises a third initialization signal line, an orthographic projection of the third initialization signal line on the base substrate extends along the column direction, and the third initialization signal line is connected to the first initialization signal line through a via hole; wherein, a first overlapping portion is provided between the orthographic projection of the third transfer portion on the base substrate and the orthographic projection of the main extension portion on the base substrate, a second overlapping portion is provided between the orthographic projection of the third initialization signal line on the base substrate and the orthographic projection of the additional portion on the base substrate, and the orthographic projection of the second auxiliary portion on the base substrate covers the first overlapping portion and the second overlapping portion.

In some embodiments of the present disclosure, the pixel driving circuit further comprises a fifth transistor, a gate of the fifth transistor is connected to an enable signal line, a first electrode of the fifth transistor is connected to a first power end, and a second electrode of the fifth transistor is connected to a second electrode of the driving transistor; the active layer further comprises: a fifth active portion, configured to form a channel region of the fifth transistor; a sixteenth active portion, connected between the fifth active portion and the third active portion, and configured to form the second electrode of the fifth transistor and the second electrode of the driving transistor; and a seventeenth active portion, connected to a side of the fifth active portion away from the sixteenth active portion, and configured to form the first electrode of the fifth transistor; and, the first conductive layer further comprises an enable signal line, an orthographic projection of the enable signal line on the base substrate extends along the row direction and covers an orthographic projection of the fifth active portion on the base substrate, and a partial structure of the enable signal line is configured to form the gate of the fifth transistor; wherein the seventeenth active portion is connected to the first power line through a via hole.

In some embodiments of the present disclosure, the pixel driving circuit further comprises a fourth transistor and a sixth transistor, a gate of the second transistor is connected to a gate signal end, and a second electrode of the second transistor is connected to the first electrode of the driving transistor, a gate of the fourth transistor is connected to a second reset signal end, a first electrode of the fourth transistor is connected to the second electrode of the driving transistor, a second electrode of the fourth transistor is connected to the second electrode of the fifth transistor, a gate of the sixth transistor is connected to the enable signal end, a first electrode of the sixth transistor is connected to the first electrode of the driving transistor, and a second electrode of the sixth transistor is connected to an anode of a light-emitting device; the active layer further comprises: a sixteenth active portion, connected to a side of the third active portion, and configured to form the second electrode of the driving transistor and the second electrode of the fifth transistor; a fourteenth active portion, connected to a second bridge portion located in a first source-drain metal layer through a via hole, the second bridge portion being further connected to the sixteenth active portion through a via hole, and the fourteenth active portion being configured to form the first electrode of the fourth transistor; a fourth active portion, connected to the fourteenth active portion, and configured to form a channel region of the fourth transistor; a fifteenth active portion, connected to a side of the fourth active portion away from the fourteenth active portion, the fifteenth active portion being configured to form the second electrode of the fourth transistor; a fifth active portion, configured to form a channel region of the fifth transistor; a sixth active portion, configured to form a channel region of the sixth transistor; a seventh active portion, configured to form a channel region of the seventh transistor; and the first conductive layer further comprises: a first reset signal line, an orthographic projection of the first reset signal line on the base substrate covering an orthographic projection of the first active portion on the base substrate, and a partial structure of the first reset signal line being configured to form a gate of the first transistor; a gate signal line, an orthographic projection of the gate signal line on the base substrate covering the orthographic projection of the second active portion on the base substrate, and a partial structure of the gate signal line being configured to form the gate of the second transistor; an enable signal line, an orthographic projection of the enable signal line on the base substrate covering an orthographic projection of the fifth active portion on the base substrate and an orthographic projection of the sixth active portion on the base substrate, a partial structure of the enable signal line being configured to form the gate of the fifth transistor, and a partial structure of the enable signal line being configured to form the gate of the sixth transistor; and a second reset signal line, an orthographic projection of the second reset signal line on the base substrate covering an orthographic projection of the fourth active portion on the base substrate and an orthographic projection of the seventh active portion on the base substrate, a partial structure of the second reset signal line being configured to form the gate of the fourth transistor, and a partial structure of the second reset signal line being configured to form a gate of the seventh transistor; wherein the orthographic projection of the first reset signal line on the base substrate, the orthographic projection of the gate signal line on the base substrate, the orthographic projection of the enable signal line on the base substrate, and the orthographic projection of the second reset signal line on the base substrate all extend along the row direction and are sequentially distributed at intervals in the column direction; and the orthographic projection of the gate signal line on the base substrate and the orthographic projection of the enable signal line on the base substrate are located on either side of the orthographic projection of the third active portion on the base substrate.

In some embodiments of the present disclosure, the display panel comprises a pixel driving circuit, the pixel driving circuit comprises a second transistor and a driving transistor, a first electrode of the second transistor is connected to a gate of the driving transistor, and the display panel further comprises: a base substrate, comprising an organic layer; an auxiliary layer, located on a side of the base substrate; an active layer, located on a side of the auxiliary layer away from the base substrate, and the active layer comprising a second active portion configured to form a channel region of the second transistor and a third active portion configured to form a channel region of the driving transistor; wherein an orthographic projection of the auxiliary layer on the base substrate covers an orthographic projection of the second active portion on the base substrate and an orthographic projection of the third active portion on the base substrate In some embodiments of the present disclosure, the display panel comprises a plurality of pixel driving circuits distributed in an array along a row direction and a column direction, the auxiliary layer comprises a plurality of auxiliary units distributed in an array along the row direction and the column direction, an auxiliary unit is provided corresponding to a pixel driving circuit, and the second active portion comprises a third active sub-portion and a fourth active sub-portion; and the auxiliary unit comprises a first auxiliary portion and a second auxiliary portion, an orthographic projection of the first auxiliary portion on the base substrate covers the orthographic projection of the third active portion on the base substrate, an orthographic projection of the second auxiliary portion on the base substrate covers an orthographic projection of the third active sub-portion on the base substrate and an orthographic projection of the fourth active sub-portion on the base substrate respectively.

In some embodiments of the present disclosure, the pixel driving circuit further comprises a first transistor, and a second electrode of the first transistor is connected to the gate of the driving transistor; the active layer further comprises a first active portion connected to a side of the second active portion, and the first active portion is configured to form a channel region of the first transistor; and the auxiliary unit further comprises a second connecting portion and a fourth auxiliary portion, the second connecting portion is respectively connected to the first auxiliary portion and the second auxiliary portion, an orthographic projection of the second connecting portion on the base substrate extends along the row direction, and two auxiliary units adjacent in the row direction are connected through the second connecting portion, the fourth auxiliary portion is connected to the second auxiliary portion, and an orthographic projection of the fourth auxiliary portion on the base substrate coves an orthographic projection of the first active portion on the base substrate.

According to another aspect of the present disclosure, there is further provided a display apparatus, including the display panel according to any embodiment of the present disclosure.

In the display panel provided by the present disclosure, the auxiliary layer is provided at the bottom of the active layer, the auxiliary layer is connected to a first signal, and the orthographic projection of the auxiliary layer on the base substrate covers the orthographic projection of the second active portion on the base substrate, that is, the auxiliary layer forms a structure for covering the channel region of the second transistor at the bottom of the active layer, so that the free charge in the bottom layer may be prevented from diffusing to the channel region of the second transistor at a high temperature, thus avoiding the influence of the free charge on the characteristics of the second transistor, and ameliorating the problem of abnormal display of the display panel that is caused by diffusion of the free charge after a high-temperature reliability test and a copper bar friction test.

It is to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of the description, illustrate embodiments consistent with the present disclosure and together with the description serve to explain the principles of the present disclosure. Obviously, the accompanying drawings in the following description are some embodiments of the present disclosure, and for those of ordinary skill in the art, other drawings may also be obtained from these drawings without creative efforts.

FIG. 1 is a schematic diagram of a circuit structure of a pixel driving circuit in a display panel according to an embodiment of the present disclosure;

FIG. 2 is a time sequence diagram of each node in a driving method for the pixel driving circuit in FIG. 1;

FIG. 3 is a structural layout of a display panel according to an embodiment of the present disclosure;

FIG. 4 is a structural layout of the auxiliary layer in FIG. 3;

FIG. 5 is a structural layout of the active layer in FIG. 3;

FIG. 6 is a stacked layout of the auxiliary layer and the active layer in FIG. 3;

FIG. 7 is a schematic diagram of connections of the auxiliary layer along the row direction and the column direction in FIG. 3;

FIG. 8 is a structural layout of the auxiliary layer in FIG. 3 according to another embodiment;

FIG. 9 is a schematic diagram of an auxiliary layer for blocking charge according to an embodiment of the present disclosure;

FIG. 10 is a structural layout of a display panel according to another embodiment of the present disclosure;

FIG. 11 is a structural layout of the auxiliary layer in FIG. 10;

FIG. 12 is a stacked layout of the auxiliary layer and the active layer in FIG. 10;

FIG. 13 is a stacked layout of the auxiliary layer, the active layer and the second conductive layer in FIG. 10;

FIG. 14 is a structural layout of a display panel according to another embodiment of the present disclosure;

FIG. 15 is a structural layout of the auxiliary layer in FIG. 14;

FIG. 16 is a stacked layout of the auxiliary layer and the active layer in FIG. 14;

FIG. 17 is a schematic diagram of connections of the auxiliary layer along the row direction and the column direction in FIG. 14;

FIG. 18 is a structural layout of a display panel according to another embodiment of the present disclosure;

FIG. 19 is a structural layout of the auxiliary layer in FIG. 18;

FIG. 20 is a stacked layout of the auxiliary layer and the active layer in FIG. 18;

FIG. 21 is a structural layout of a display panel according to another embodiment of the present disclosure;

FIG. 22 is a structural layout of the auxiliary layer in FIG. 21;

FIG. 23 is a stacked layout of the auxiliary layer and the active layer in FIG. 21;

FIG. 24 is a stacked layout of the auxiliary layer, the active layer and the second conductive layer in FIG. 21;

FIG. 25 to FIG. 34 are structural layouts of the auxiliary layer and stacked layouts of the auxiliary layer and the active layer according to other embodiments of the present disclosure;

FIG. 35 is a structural layout of an auxiliary layer according to another embodiment of the present disclosure;

FIG. 36 is a structural layout of the first conductive layer in FIG. 3;

FIG. 37 is a structural layout of the second conductive layer in FIG. 3;

FIG. 38 is a structural layout of the first source-drain metal layer in FIG. 3;

FIG. 39 is a structural layout of the second source-drain metal layer in FIG. 3;

FIG. 40 is a stacked layout of the auxiliary layer, the active layer and the first source-drain metal layer in FIG. 3;

FIG. 41 is a stacked layout of the auxiliary layer, the first conductive layer and the first source-drain metal layer in FIG. 3;

FIG. 42 is a cross-sectional view taken along line AA in FIG. 3.

### DETAILED DESCRIPTION

Example implementations will now be described more fully with reference to the accompanying drawings. However, the example embodiments can be implemented in a variety of forms and should not be construed as limited to the embodiments set forth here. By contrast, these embodiments are provided so that this disclosure will be thorough and complete, and will fully convey the concepts of example implementations to those skilled in the art. The same reference numerals in the figures denote the same or similar structures, and thus their detailed description will be omitted. In addition, the figures are merely schematic illustrations of the present disclosure and are not necessarily drawn to scale.

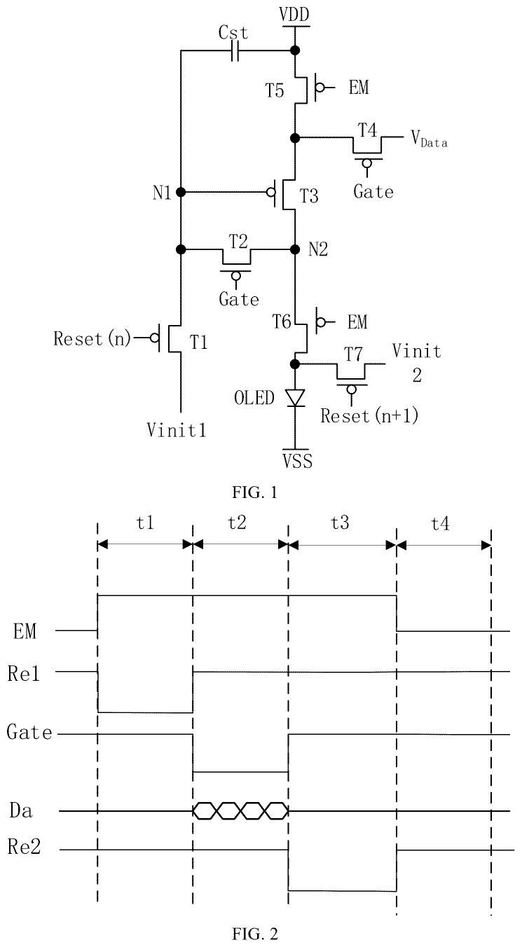

FIG. 1 is a schematic diagram of a circuit structure of a pixel driving circuit in a display panel according to an embodiment of the present disclosure. The pixel driving circuit may include a first transistor T1, a second transistor T2, a driving transistor T3, a fourth transistor T4, a fifth transistor TS, a sixth transistor T6, a seventh transistor T7, and a storage capacitor C. Among them, a first electrode of the first transistor T1 is connected to a first initial signal end Vinit1, a second electrode of the first transistor T1 is connected to a first node N1, and a gate of the first transistor T1 is connected to a first reset signal end Reset (N); a first electrode of the second transistor T2 is connected to a gate of the driving transistor T3, a second electrode of the second transistor T2 is connected to a first electrode of the driving transistor, and a gate of the second transistor T2 is connected to a gate signal end Gate; the gate of the driving transistor T3 is connected to the first node N1; a second electrode of the fourth transistor T4 is connected to a data signal end VData, a first electrode of the fourth transistor T4 is connected to the second electrode of the driving transistor T3, and a gate of the fourth transistor T4 is connected to the gate signal end Gate; a second electrode of the fifth transistor T5 is connected to the second electrode of the driving transistor T3, a first electrode of the fifth transistor T5 is connected to a first power end VDD, and a gate of the fifth transistor T5 is connected to a enable signal end EM; a first electrode of the sixth transistor T6 is connected to the first electrode of the driving transistor T3, and a gate of the sixth transistor T6 is connected to the enable signal end EM; a first electrode of the seventh transistor T7 is connected to a second initial signal end Vinit2, a second electrode of the seventh transistor T7 is connected to the second electrode of the sixth transistor T6, and a gate of the seventh transistor T7 is connected to a second reset signal end Reset (n+1); a first electrode of the storage capacitor C is connected to the first node N1, and a second electrode of the storage capacitor C is connected to the first power end VDD. The pixel driving circuit may be connected to a light-emitting unit OLED for driving the light-emitting unit OLED to emit light, and the light-emitting unit OLED may be connected between the second electrode of the sixth transistor T6 and a second power end VSS. Among them, each transistor in the present disclosure may be a P-type transistor; for example, the first transistor T1 to the seventh transistor T7 may each be a P-type low-temperature poly-silicon transistor. The P-type low-temperature poly-silicon transistor has a relatively high carrier mobility, thus facilitating the implementation of a display panel having a high resolution, a high response speed, a high pixel density, and a high aperture ratio. A same voltage signal or different voltage signals may be output from the first initial signal end Vinit1 and the second initial signal end Vinit2 according to actual situations.

It should be noted that the transistors used in the embodiments of the present disclosure may all be thin film transistors or field effect transistors or other devices with the same characteristics. In the present description, the first electrode may be a drain electrode, the second electrode may be a source electrode; or, the first electrode may be a source electrode, and the second electrode may be a drain electrode. FIG. 2 is a time sequence diagram of each node in the driving method for the pixel driving circuit in FIG. 1. As shown in FIG. 2, Gate represents the time sequence of the gate signal end Gate, Re1 represents the time sequence of the first reset signal end Reset (n), Re2 represents the time sequence of the second reset signal end Reset (n+1), EM represents the time sequence of the enable signal end EM, and Da represents the time sequence of the data signal end VData. The driving method for the pixel driving circuit may include a first reset stage t1, a compensation stage t2, a second reset stage t3, and a light-emitting stage t4. In the first reset stage t1, a low level signal is output from the first reset signal end Reset (n), the first transistor T1 is turned on, and a first initial signal is input from the first initial signal end Vinit1 to the first node N1. In the compensation stage t2, a low level signal is output from the gate signal end Gate, the second transistor T2 and the fourth transistor T4 are turned on, and a data signal is output from the data signal end VData to write the voltage Vdata+Vth (i.e., the sum of the voltage Vdata and the voltage Vth) to the first node N1, where Vdata is the voltage of the driving signal, and Vth is the threshold voltage of the driving transistor T3. In the second reset stage t3, a low level signal is output from the second reset signal end Reset (n+1), the seventh transistor T7 is turned on, and a second initial signal is input from the second initial signal end Vinit2 to the second electrode of the sixth transistor T6. In the light-emitting stage t4, a low level signal is output from the enable signal end EM, the sixth transistor T6 and the fifth transistor T5 are turned on, and the driving transistor T3 provides a driving current under the action of the voltage Vdata+Vth stored in the storage capacitor C, so that the light-emitting device OLED emits light.

According to the output current formula for the driving transistor I=(μWCox2L) (Vgs−Vth)², where u is the carrier mobility, Cox is the gate storage capacitance per unit area, W is the width of the channel of the driving transistor, L is the length of the channel of the driving transistor, Vgs is the voltage difference between the gate and the source of the driving transistor, and Vth is the threshold voltage of the driving transistor, the output current of the driving transistor in the pixel driving circuit of the present disclosure is I=(μWCox/2L) (Vdata+Vth−Vdd−Vth)². In the pixel driving circuit, the influence of the change of the threshold voltage of the driving transistor on the output current of the driving transistor may be avoided.

In the related art, the light-emitting efficiency of the light-emitting device is higher and higher, so as to meet the requirements of higher service life and lower power consumption of the display device. However, too high light-emitting efficiency makes the light-emitting device more sensitive to the characteristic change of the TFT, and the characteristics of the TFT in the display panel may be affected after a reliability test. Furthermore, since the light-emitting efficiency of each device is different from each other, the problem of color shift in the display panel is caused due to the charge moving into the active layer Poly after a reliability test or a copper bar friction test. In addition, when a user uses a terminal product such as a mobile phone, the charge on the hand may be gathered on the display panel; and, if the user uses the screen for a long time and in a high frequency, it may cause the charge to affect the characteristics of the TFT, so as to generate a defect of local color shift in the place where the static electricity is gathered. The display panel of the present disclosure is used to solve the above problems.

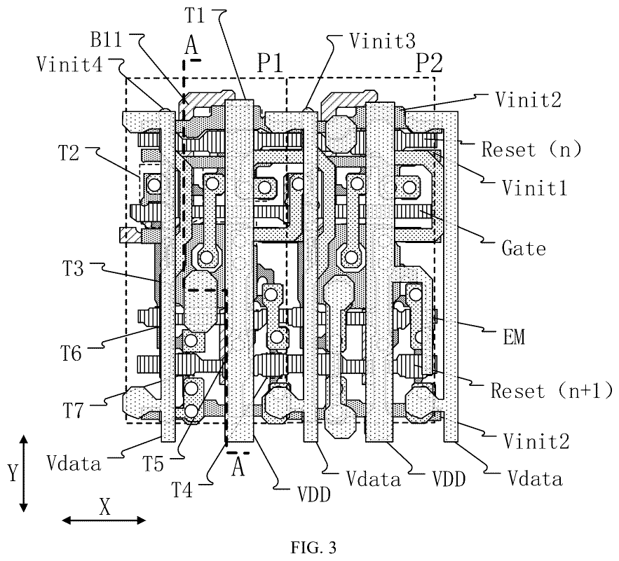

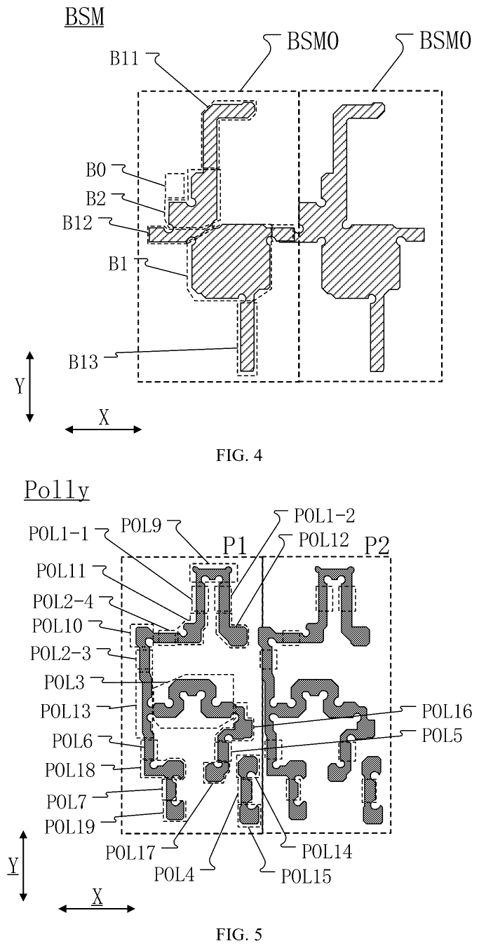

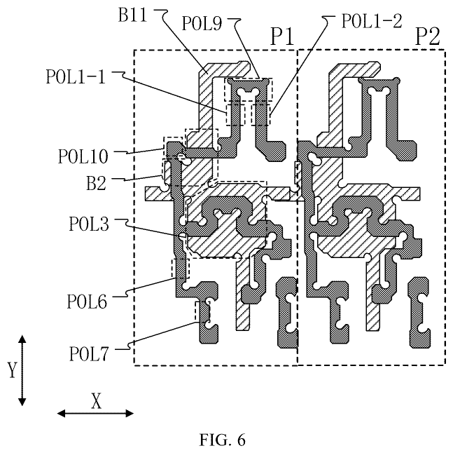

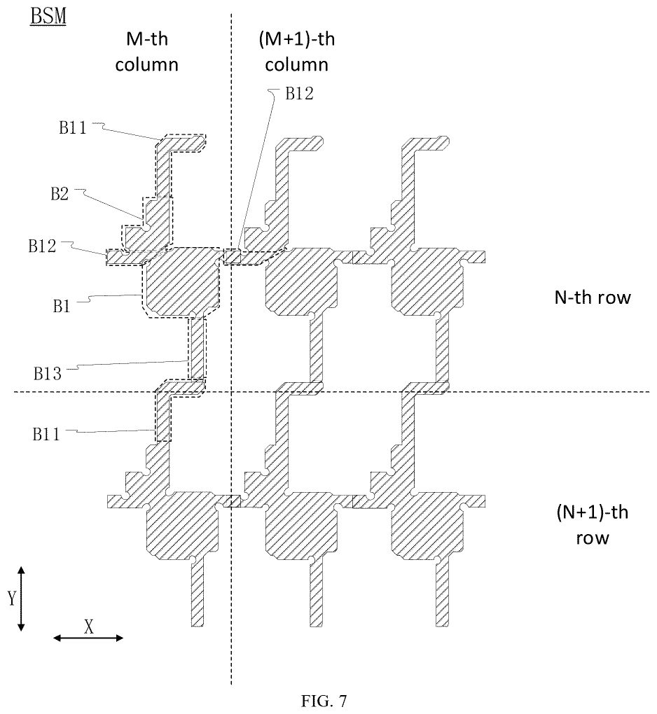

The display panel provided by the present disclosure may include a plurality of pixel driving circuits distributed in an array along a row direction X and a column direction Y. The pixel driving circuit is configured to drive the light-emitting device to emit light. The row direction X intersects the column direction Y. The pixel driving circuit may include a second transistor T2 and a driving transistor T3, and a first electrode of the second transistor T2 is connected to a gate of the driving transistor T3. The pixel driving circuit may be as shown in FIG. 1. Of course, in other example embodiments, the pixel driving circuit in the display panel may also be of another structure, such as a structure of 8T1C, 9T1C, or the like. FIG. 3 is a structural layout of a display panel according to an embodiment of the present disclosure, FIG. 4 is a structural layout of the auxiliary layer in FIG. 3, FIG. 5 is a structural layout of the active layer in FIG. 3, FIG. 6 is a stacked layout of the auxiliary layer and the active layer in FIG. 3, FIG. 7 is a schematic diagram of connections of the auxiliary layer along the row direction and the column direction in FIG. 3, and FIG. 8 is a structural layout of the auxiliary layer in FIG. 3 according to another embodiment. As shown in FIG. 3 to FIG. 8, the display panel may further include a base substrate, an auxiliary layer BSM, and an active layer Poly; where, the auxiliary layer BSM is located on a side of the base substrate, and the auxiliary layer BSM may be connected or not connected to a first signal; the active layer Poly is located on a side of the auxiliary layer BSM away from the base substrate, the active layer Poly includes a second active portion POL2 and a third active portion POL3, the second active portion POL2 is configured to form a channel region of the second transistor T2, and the third active portion POL3 is configured to form a channel region of the driving transistor T3; and, an orthographic projection of the auxiliary layer BSM on the base substrate covers an orthographic projection of the second active portion POL2 on the base substrate and an orthographic projection of the third active portion POL3 on the base substrate.

In the display panel provided by the present disclosure, the auxiliary layer BSM is provided at the bottom of the active layer Poly, and the orthographic projection of the auxiliary layer BSM on the base substrate covers the orthographic projection of the second active portion POL2 on the base substrate, that is, the auxiliary layer BSM forms a structure for covering the channel region of the second transistor T2 at the bottom of the active layer Poly, so that the free charge in the bottom layer may be blocked from diffusing to the channel region of the second transistor T2 at a high temperature, thus avoiding the influence of the free charge on the characteristics of the second transistor T2, and ameliorating the problem of abnormal display of the display panel that is caused by diffusion of the free charge after a high-temperature reliability test and a copper bar friction test.

The base substrate of the present disclosure may be a flexible base substrate, for example, the base substrate may be a flexible substrate of a PI material. A large amount of free charges is present in the flexible base substrate, and after the temperature rises, the free charges may diffuse to the channel region of the transistor, resulting in forward drift of the threshold voltage of the transistor. Taking the pixel driving circuit shown in FIG. 1 as an example, after a forward drift of the threshold voltage of the second transistor T2, it may cause the voltage at the first node NI to be decreased, so that the gate source voltage of the driving transistor T3 is decreased accordingly, and the driving current provided by the pixel driving circuit is increased, thus causing the screen to be brighter than that before the reliability test. In addition, since the light-emitting efficiency of the G sub-pixel is the highest, the problem of brighter display after a friction test is generally represented as green display after the test, and the phenomenon is easier to be perceived by the human eye during low-grayscale display, that is, the phenomenon is more obvious during low grayscale.

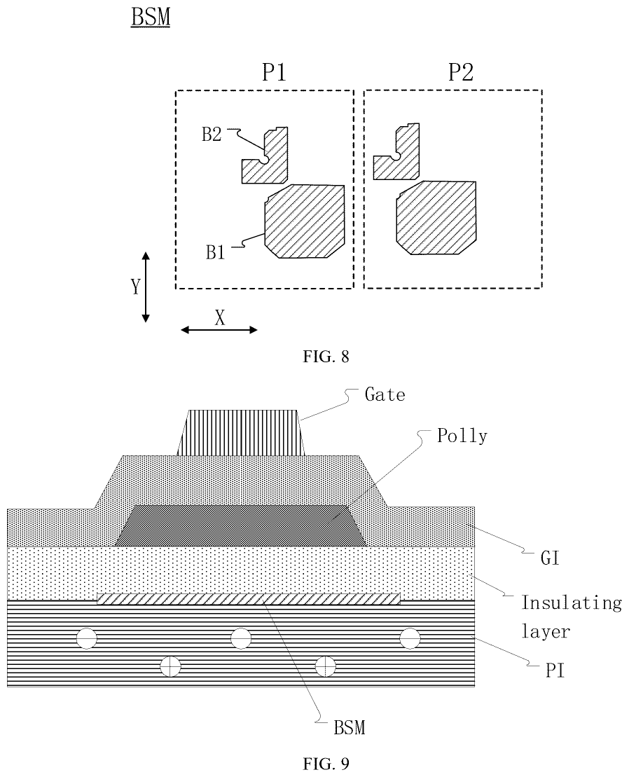

The orthographic projection of a certain structure A on the base substrate covering the orthographic projection of the other structure B on the base substrate in the present disclosure may be understood as that the contour of the projection of the structure B on the plane of the base substrate is completely located within the contour of the projection of the structure A on the same plane. In the present disclosure, the orthographic projection of the auxiliary layer BSM on the base substrate covers the orthographic projection of the second active portion POL2 on the base substrate, that is, the contour of the orthographic projection of the second active portion POL2 on the base substrate is completely located within the contour of the orthographic projection of the auxiliary layer BSM on the base substrate. In this way, it is equivalent to that the auxiliary layer BSM forms a structure for covering the channel region of the second transistor T2 at the bottom of the active layer Poly. As shown in FIG. 9, the free charge may be intercepted by the auxiliary layer BSM and may not be diffused to the active layer Poly, so that the channel stability of the second transistor T2 is ensured, and the problem of forward drift of the threshold voltage of the second transistor T2 is avoided, thus reducing the characteristic difference of the transistor after the high-temperature reliability test, and ameliorating the problem of abnormal display of the display panel after the high-temperature reliability test.

For example, the orthographic projection of the auxiliary layer BSM on the base substrate covering the orthographic projection of the second active portion POL2 on the base substrate is equivalent to that, there is an auxiliary layer structure below the second active portion POL2, and the auxiliary layer structure is opposite to the second active part POL2 and has a larger area than the second active part POL2. That is, the boundary of the auxiliary layer structure goes beyond the boundary of the second active portion POL2. Obviously, the auxiliary layer structure can block the free charge from being diffused to the second active portion POL2, thus reducing the characteristic difference of the second transistor T2 before and after the high-temperature reliability test, and avoiding the problem of abnormal display after the reliability test.

It should be noted that, when the auxiliary layer BSM in the present disclosure is connected or not connected to the first signal, the auxiliary layer BSM both can block the free charge from entering the channel region of the transistor. When the auxiliary layer BSM is not connected to the first signal, since the auxiliary layer BSM has no potential, the auxiliary layer BSM will not form a parasitic effect with other electric conductors, and thus the transistor will not be affected. When the auxiliary layer BSM is connected to the first signal, the auxiliary layer BSM forms an equipotential surface, so that the barrier effect on the free charge may be improved. Secondly, the threshold voltage of the transistor in the pixel circuit may drift after working for a long time, and the threshold voltage of the transistor may be corrected and recovered by setting the auxiliary layer and connecting the auxiliary layer to a voltage signal, so that the display effect of the display panel may also be improved. Among them, the first signal may be a constant voltage signal. For example, the first signal may be a voltage signal provided by the first power end VDD in FIG. 1, or, may be an initialization signal provided by the first initial signal end Vinit1 or the second initial signal end Vinit2 in FIG. 1.

In addition, the auxiliary layer BSM in the present disclosure may be a metal auxiliary layer formed of a metal material, such as at least one of silver, copper, molybdenum, titanium, aluminum, or the like. The auxiliary layer BSM may also be a transparent conductive layer, such as at least one of indium tin oxide (ITO), cadmium stannate (TCO), graphene, metal nanowires, carbon nanotubes, or the like. Alternatively, the auxiliary layer BSM may also be an auxiliary layer formed after a semiconductor material layer is subjected to a conductorization treatment, for example, a semiconductor material such as doped poly-silicon or amorphous silicon, etc. Alternatively, the auxiliary layer BSM may be a semiconductor material, such as monocrystalline silicon, amorphous silicon, poly-silicon, microcrystalline silicon, or the like. The material of the auxiliary layer BSM is not specifically limited in the present disclosure.

The solution of the present disclosure will be further described below with reference to the accompanying drawings.

As shown in FIG. 3 and FIG. 5, the active layer Poly may include a first active portion POL1 to a nineteenth active portion POL19. The first active portion POL1 may be configured to form a channel region of the first transistor T1, the second active portion POL2 may be configured to form a channel region of the second transistor T2, the third active portion POL3 may be configured to form a channel region of the driving transistor T3, and the fourth active portion POL4 to the seventh active portion POL7 are configured to form channel regions of the fourth transistor T4 to the seventh transistor T7 respectively. The active layer Poly in the present disclosure may form the various transistors in the pixel driving circuit with the third active portion POL3 as the center. The active layer Poly in the present disclosure may be formed of a poly-silicon semiconductor material, and correspondingly, the transistor in the display panel of the present disclosure may be a P-type low temperature poly-silicon thin film transistor.

In the example embodiment, the first transistor T1 and the second transistor T2May be of dual-gate structures. Therefore, the first active portion POL1 may include a first active sub-portion POL1-1 and a second active sub-portion POL1-2. The first active sub-portion POL1-1 and the second active sub-portion POL1-2 are configured to form two channel regions of the first transistor T1 respectively, and the first active sub-portion POL1-1 and the second active sub-portion POL1-2 are connected through the ninth active portion POL9. That is, the ninth active portion POL9 is configured to connect the two channels of the first transistor T1, thus forming a conductorization structure TIM between the two channels of the first transistor T1. The second active portion POL2 may include a third active sub-portion POL2-3 and a fourth active sub-portion POL2-4, the third active sub-portion POL2-3 and the fourth active sub-portion POL2-4 are configured to form two channel regions of the second transistor T2 respectively, and the third active sub-portion POL2-3 and the fourth active sub-portion POL2-4 may be connected through the tenth active portion POL10. That is, the tenth active portion POL 10 is configured to connect the two channels of the second transistor T2, thus forming a conductorization structure T2M between the two channels of the second transistor T2.

The eleventh active portion POL11 is connected between the first active sub-portion POL1-1 and the fourth active sub-portion POL2-4, and may be configured to form the second electrode of the first transistor T1 and the first electrode of the second transistor T2. The eleventh active portion POL11 may be connected to the first bridge portion 31 of the first source-drain metal layer SD1 layer through a via hole, so as to connect the second electrode of the first transistor T1 and the first electrode of the second transistor T2 to the gate of the driving transistor T3 through the first bridge portion 31.

The twelfth active portion POL12 may be configured to form the second electrode of the first transistor T1. In some embodiments, the display panel may include a first pixel column P1 and a second pixel column P2 that are sequentially and alternately distributed along the row direction X. In each pixel driving circuit of the first pixel column P1, the twelfth active portion POL12 may be connected to the third initialization signal line Vinit3 in the first source-drain metal layer SD1 through a via hole, so as to connect the twelfth active portion POL12 to the first initialization signal line Vinit1 through the third initialization signal line Vinit3. In each pixel driving circuit of the second pixel column P2, the twelfth active portion POL12 may be connected to the third bridge portion 33 in the first source-drain metal layer SD1 through a via hole, so as to connect the twelfth active portion POL12 to the first initialization signal line Vinit1 through the third bridge portion 33.

The thirteenth active portion POL13 is connected between the third active sub-portion POL2-3 and the third active portion POL3. The thirteenth active portion POL13 may be configured to form the second electrode of the second transistor T2, the first electrode of the sixth transistor T6, and the first electrode of the driving transistor T3.

The sixteenth active portion POL16 is connected between the fifth active portion POL5 and the third active portion POL3. The sixteenth active portion POL16 may be configured to form the second electrode of the driving transistor T3 and the second electrode of the fifth transistor T5.

The seventeenth active portion POL17 is connected to a side of the fifth active portion POL5 away from the sixteenth active portion POL16, and the seventeenth active portion POL 17 may be configured to form the first electrode of the fifth transistor T5. The seventeenth active portion POL17 located in each pixel driving circuit of the first pixel column P1 may be connected to the first power transfer line VDDL1 in the first source-drain metal layer SD1 through a via hole, so as to be connected to the first power line VDD in the second source-drain metal layer SD2 through the first power transfer line VDDL1. The seventeenth active portion POL17 located in the second pixel column P2 may be connected to the second power transfer line VDDL2 in the first source-drain metal layer SD1 through a via hole, so as to be connected the first power line VDD in the second source-drain metal layer SD2 through the second power transfer line VDDL2, so that the first electrode of the fifth transistor T5 is connected to the first power end through the first power transfer line VDDL1 and the second power transfer line VDDL2, respectively.

The fourteenth active portion POL14 and the fifteenth active portion POL15 are connected to either side of the fourth active portion POL4, the fourteenth active portion POL14 may be configured to form the first electrode of the fourth transistor T4, and the fifteenth active portion POL15 may be configured to form the second electrode of the fourth transistor T4. The fourteenth active portion POL14 may be connected to the second bridge portion 32 in the first source-drain metal layer SD1 through a via hole, so as to connect the first electrode of the fourth transistor T4 to the second electrode of the driving transistor T3 through the second bridge portion 32. The fifteenth active portion POL15 may be connected to the data transfer portion VdataL located in the first source-drain metal layer SD1 through a via hole, so as to be connected to the data signal line Vdata in the second source-drain metal layer SD2 through the data transfer portion VdataL, thus connecting the second electrode of the fourth transistor T4 to the data signal end.

The eighteenth active portion POL18 is connected between the sixth active portion POL6 and the seventh active portion POL7. The eighteenth active portion POL18 may be configured to form the second electrode of the sixth transistor T6 and the second electrode of the seventh transistor T7. The eighteenth active portion POL18 may be connected to the anode transfer portion 35 in the first source-drain metal layer SD1 through a via hole, so as to connect the second electrode of the sixth transistor T6 and the second electrode of the seventh transistor T7 to the anode of the light-emitting device through the anode transfer portion 35.

The nineteenth active portion POL19 is connected to the other side of the seventh active portion POL7, the nineteenth active portion POL19 may be configured to form the first electrode of the seventh transistor T7, and the nineteenth active portion POL19 may be connected to the second initialization signal line Vinit2 in the second conductive layer Gate2 through a via hole, so as to connect the first electrode of the seventh transistor T7 to the second initial signal end.

As shown in FIG. 3 and FIG. 4, in some embodiments, the auxiliary layer BSM may include a plurality of auxiliary units BSM0, the plurality of auxiliary units BSM0 are distributed in an array along the row direction and the column direction, and a pixel driving circuit is correspondingly provided with an auxiliary unit BSM0.

As shown in FIG. 4, the auxiliary unit BSM0 may include a second auxiliary portion B2. The second auxiliary portion B2 may be provided corresponding to the second active portion POL2, that is, the second auxiliary portion B2 is provided below the second active portion POL2. As described above, in the display panel of the present disclosure, the second transistor T2 may be of a double-gate structure. As shown in FIG. 6, the orthographic projection of the second auxiliary portion B2 on the base substrate may respectively cover the orthographic projection of the third active sub-portion POL2-3 on the base substrate and the orthographic projection of the fourth active sub-portion POL2-4 on the base substrate. In this way, the channel region of the second transistor T2 may be isolated from the free charge in the bottom layer through the second auxiliary portion B2. In addition, in the example embodiment, the orthographic projection of the second auxiliary portion B2 on the base substrate may not overlap with the orthographic projection of the tenth active portion POL 10 on the base substrate, that is, the second auxiliary portion B2 does not block the tenth active portion POL10. In other words, the auxiliary unit BSM0 only blocks the channel region of the second transistor T2, but does not block the conductorization structure T2M between the two channels of the second transistor T2. For example, as shown in FIG. 4, the second auxiliary portion B2 may be provided with a notch B0, and the orthographic projection of the tenth active portion POL10 on the base substrate is located within the orthographic projection of the notch B0 on the base substrate, so that the second auxiliary portion B2 does not block the tenth active portion POL 10.

As shown in FIG. 4 and FIG. 6, in the example embodiment, the auxiliary unit BSM0 may further include a first auxiliary portion B1, the first auxiliary portion B1 is connected to the second auxiliary portion B2, and the first auxiliary portion B1 is provided corresponding to the third active portion POL3. The orthographic projection of the first auxiliary portion B1 on the base substrate may cover the orthographic projection of the third active portion POL3 on the base substrate. That is, the auxiliary layer BSM is further provided with a metal isolation structure at the position corresponding to the channel region of the driving transistor T3, which blocks the channel region of the driving transistor T3. In this way, the auxiliary layer BSM may block the charge generated by friction from entering the third active portion POL3, thus avoiding the problem of brighter display after a copper bar friction test and a high-temperature reliability test.

It should be understood that the orthographic projection of a certain structure A on the base substrate covering the orthographic projection of the other structure B on the base substrate in the present disclosure may be understood as that the contour of the projection of the structure B on the plane of the base substrate is completely located within the contour of the projection of the structure A on the same plane.

As shown in FIG. 4, in some embodiments, the auxiliary unit BSM0 may further include a first connecting portion B11 to a third connecting portion B13, the first connecting portion B11 is connected to the side of the second auxiliary portion B2 away from the first auxiliary portion B1 along the column direction, and the orthographic projection of the first connecting portion B11 on the base substrate does not overlap with the orthographic projection of the first active portion POL1 on the base substrate. That is, the region covered by the orthographic projection of the first connecting portion B11 on the base substrate is avoided from the region covered by the orthographic projection of the first active portion POL1 on the base substrate. In other words, there is no auxiliary layer structure provided below the first active portion POL1.

The second connecting portion B12 is connected to the side of the first auxiliary portion B1 in the row direction, and the orthographic projection of the second connecting portion B12 on the base substrate may extend along the row direction. The third connecting portion B13 is connected to the side of the first auxiliary portion B1 away from the second auxiliary portion B2 in the column direction, and the orthographic projection of the third connecting portion B13 on the base substrate extends along the column direction. As shown in FIG. 7, in two auxiliary units BSM0 adjacent in the row direction, the second connecting portion B12 in one auxiliary unit BSM0 is connected to the first auxiliary portion B1 in the other auxiliary unit BSM0, that is, the two auxiliary units BSM0 adjacent in the row direction are connected through the second connecting portion B12. In the two auxiliary units BSM0 adjacent in the column direction, the third connecting portion B13 in the previous row is connected to the first connecting portion B11 in the next row, that is, the two auxiliary units BSM0 adjacent in the column direction are connected through the third connecting portion B13. Therefore, the various auxiliary units BSM0 in the auxiliary layer BSM form a grid structure in a crisscross manner, and the grid structure may reduce the IR drop of the first signal connected to the grid structure, thus reducing the voltage drop loss. In addition, an equipotential surface is formed in the grid structure formed by the auxiliary layer BSM, so that the auxiliary effect on the free charge in the active layer may be improved, which is beneficial for the characteristic stability of each transistor in the pixel driving circuit.

In addition, in some embodiments, the auxiliary layer BSM may not be connected to the first signal. For example, as shown in FIG. 8, the auxiliary unit BSM0 may not include a connecting portion, that is, each auxiliary portion in the auxiliary unit BSM0 may be an isolated structure. For example, in FIG. 8, the first auxiliary portion B1 and the second auxiliary portion B2 are not connected to each other, two adjacent auxiliary units BSM0 are not connected to each other either, and the free charge may also be blocked from entering the transistors at the corresponding positions through the independent auxiliary portions. In addition, it should be understood that, in FIG. 8, it is described only by taking that the auxiliary portion is provided below the second transistor T2 and the driving transistor T3 as an example, and the auxiliary unit BSM0 may further include more isolated auxiliary portions to block the various transistors, which will not be elaborated on one by one here.

A certain structure A extending along the B direction described in the present disclosure refers to that A may include a main portion and a secondary portion connected with the main portion, the main portion is a body with a shape of a line, a line segment or a strip, the main portion extends along the B direction, and the length of the main portion extending along the B direction is greater than the length of the secondary portion extending along other directions.

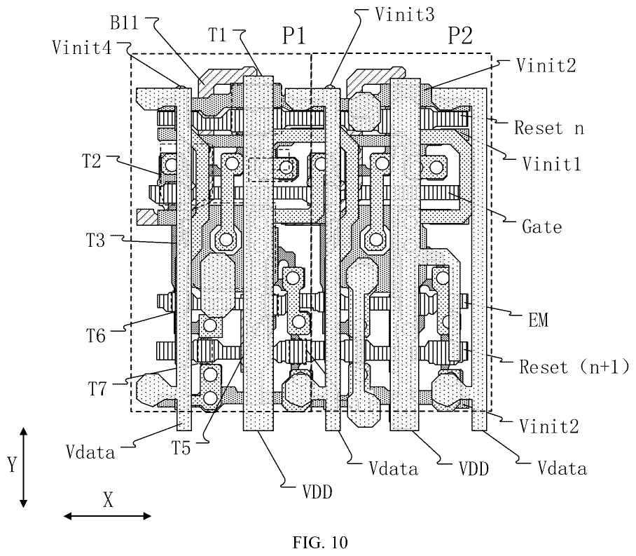

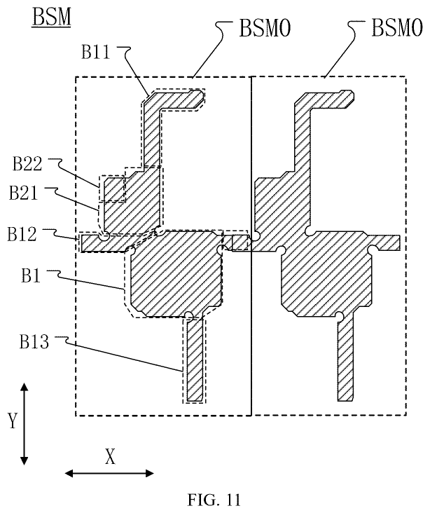

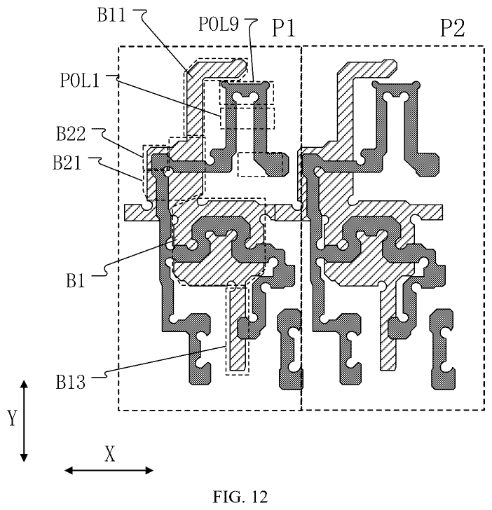

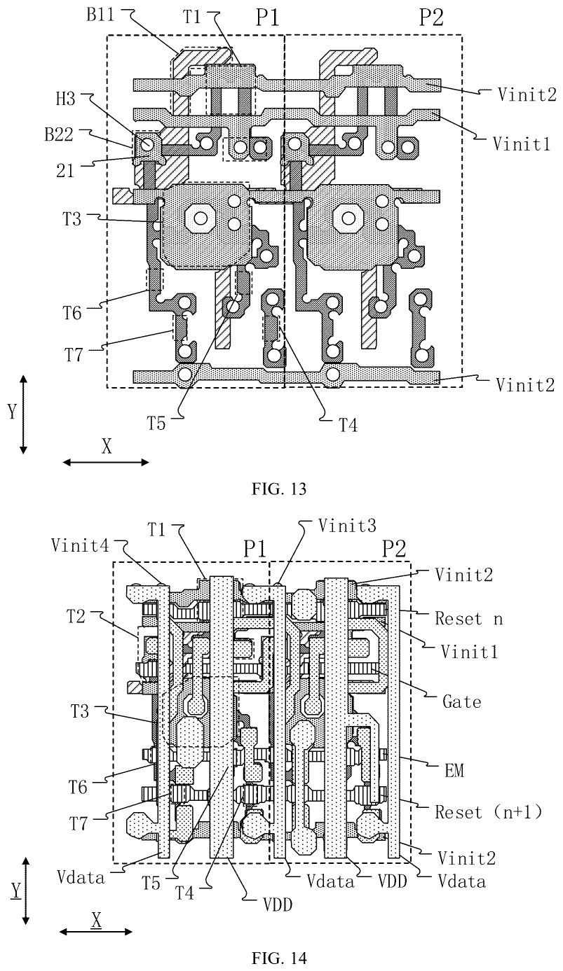

FIG. 10 is a structural layout of a display panel according to another embodiment of the present disclosure; FIG. 11 is a structural layout of the auxiliary layer in FIG. 10; FIG. 12 is a stacked layout of the auxiliary layer and the active layer in FIG. 10; and FIG. 13 is a stacked layout of the auxiliary layer, the active layer and the second conductive layer in FIG. 10. The active layer Poly to the second source-drain metal layer SD2 in the display panel shown in FIG. 10 are provided with all features corresponding to the active layer Poly to the second source-drain metal layer SD2 in the display panel in FIG. 3. In addition, it should be understood that the via hole shown in FIG. 13 is an insulating layer provided on the second conductive layer Gate2, and the metal structure corresponding to the via hole position in the Gate2 layer is connected to a corresponding structure in the first source-drain metal layer SD1 through the via hole.

Based on the above embodiments, as shown in FIG. 10 and FIG. 11, in the example embodiment, the second auxiliary portion B2 may include a first auxiliary sub-portion B21 and a second auxiliary sub-portion B22, the orthographic projection of the first auxiliary sub-portion B21 on the base substrate covers the orthographic projection of the third active sub-portion POL2-3 on the base substrate and the orthographic projection of the fourth active sub-portion POL2-4 on the base substrate, and the orthographic projection of the second auxiliary sub-portion B22 on the base substrate covers the orthographic projection of the tenth active portion POL 10 on the base substrate. That is, there is also provided a corresponding auxiliary sub-portion below the conductorization structure T2M between the two channels of the second transistor T2 for charge blocking. Therefore, in the example embodiment, the second auxiliary portion B2 not only blocks the two channels of the second transistor T2, but also blocks the conductorization structure T2M between the two channels of the second transistor T2, so that the auxiliary unit BSM0 may further block the charge from entering the conductorization structure T2M connected between the two channels of the second transistor T2. Since the second transistor T2 is turned on in the data writing stage, it has a significant impact on the driving current provided by the driving circuit. Therefore, in the example embodiment, by providing the second auxiliary sub-portion B22, the overall stability of the second transistor T2 may be further improved, and the characteristic offset of the second transistor T2 before and after the high-temperature reliability test and the copper bar friction test may be avoided, thus further ensuring that the problem of color shift of the display panel before and after the test may not occur.

Furthermore, as shown in FIG. 13, in some embodiments, the second conductive layer Gate2 is generally provided with a first conductive block 21, the first conductive block 21 is located above the tenth active portion POL10, and the first conductive block 21 is connected to the first power line VDD in the second source-drain metal layer SD2 through the third via hole H3 in the interlayer dielectric layer, so as to provide a stable voltage source for the first conductive block 21 through the first power line VDD, thus voltage stabilization may be performed on the tenth active portion POL10 through the first conductive block 21. On this basis, the orthographic projection of the second sub-auxiliary portion B22 on the base substrate further covers the orthographic projection of the third via hole H3 on the base substrate, that is, the region covered by the orthographic projection of the third via hole H3 on the base substrate is completely located within the region covered by the orthographic projection of the second sub-auxiliary portion B22 on the base substrate, so as to ensure that a flat auxiliary layer structure is provided below the third through hole H3, thus a thickness segment difference does not exist below the third through hole H3, and deformation of the third via hole H3 may be avoided. If the third via hole H3 is deformed, a capacitance change of the auxiliary layer BSM and the second conductive layer Gate2 at the conductorization structure T2M of the second transistor T2 may occur. Therefore, when the third via hole H3 is deformed due to process fluctuation, a problem of display stripe may occur between different sub-pixels due to a capacitance difference between the conductorization structure T2M of the second transistor T2 and the second conductive layer Gate2. In the example embodiment, the region covered by the orthographic projection of the third via hole H3 on the base substrate is completely located within the region covered by the orthographic projection of the second sub-auxiliary portion B22 on the base substrate, so as to avoid the defect of Mura display caused by different capacitances of the auxiliary layer BSM and the second conductive layer Gate2 at the tenth active portion POL10 between different sub-pixels.

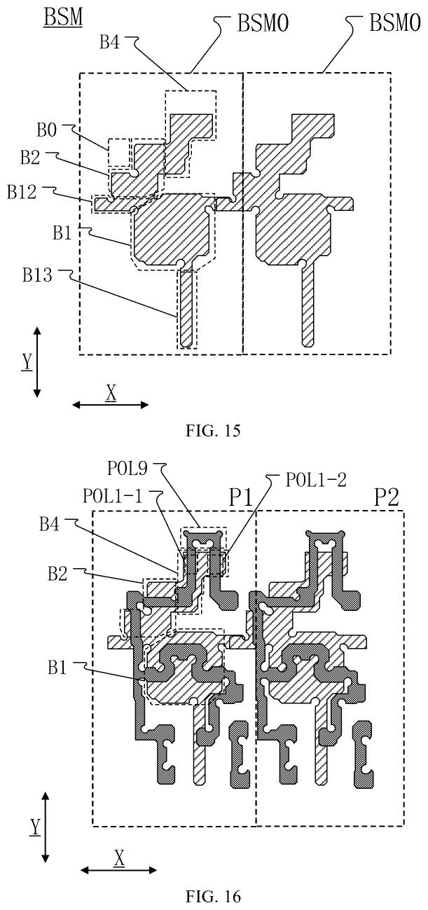

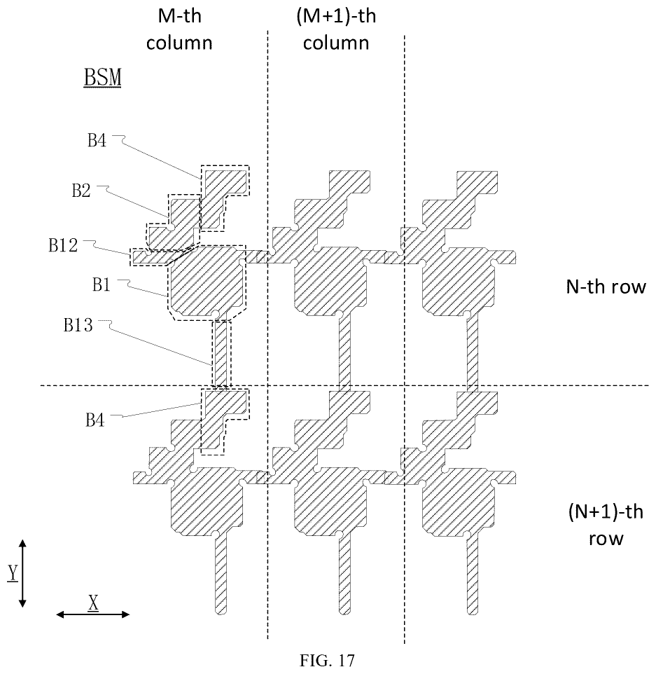

FIG. 14 is a structural layout of a display panel according to another embodiment of the present disclosure, FIG. 15 is a structural layout of the auxiliary layer in FIG. 14, FIG. 16 is a stacked layout of the auxiliary layer and the active layer in FIG. 14, and FIG. 17 is a schematic diagram of connections of the auxiliary layer along the row direction and the column direction in FIG. 14. The active layer Poly to the second source-drain metal layer SD2 in the display panel shown in FIG. 14 are provided with all features corresponding to the active layer Poly to the second source-drain metal layer SD2 in the display panel in FIG. 3.

On the basis of the foregoing embodiments, as shown in FIG. 14, FIG. 15, and FIG. 17, the difference from the layout structure shown in FIG. 3 is that, in the example embodiment, the auxiliary unit BSM0 may further include a fourth auxiliary portion B4 provided corresponding to the first active portion POL1, the fourth auxiliary portion B4 is connected to the second auxiliary portion B2, and an orthographic projection of the fourth auxiliary portion B4 on the base substrate may cover an orthographic projection of the first active portion POL 1 on the base substrate. That is, the auxiliary unit BSM0 in the example embodiment is not provided with a first connecting portion B11. In this structure, in two auxiliary units BSM0 adjacent in the column direction, the third connecting portion B13 in the previous row is connected to the fourth auxiliary portion B4 in the next row, so that the various auxiliary units BSM0 in the same column are connected in sequence, and meanwhile, the various auxiliary units BSM0 in the same row are also connected in sequence. Therefore, in the layout structure shown in FIG. 14, the auxiliary layer BSM also has a grid structure in a crisscross manner.

As described in the above, the first active portion POL1 may include the first active sub-portion POL 1-1 and the second active sub-portion POL1-2. As shown in FIG. 14 and FIG. 16, in the example embodiment, the orthographic projection of the fourth auxiliary portion B4 on the base substrate may specifically cover the orthographic projection of the first active sub-portion POL1-1 on the base substrate and the orthographic projection of the second active sub-portion POL 1-2 on the base substrate. That is, the region covered by the orthographic projection of the first active sub-portion POL1-1 on the base substrate and the orthographic projection of the second active sub-portion POL1-2 on the base substrate is completely located within the region covered by the orthographic projection of the fourth auxiliary portion B4 on the base substrate. Therefore, the auxiliary layer BSM blocks the first active portion POL1 through the fourth auxiliary portion B4, so as to block the free charge from entering the first active portion POL1, thus ensuring that the characteristics of the first transistor T1 before and after the high-temperature reliability test and the copper bar friction test remain stable. It may be known that, after the free charge enters the channel region of the first transistor T1, it may result in a forward shift of the threshold voltage of the first transistor T1, the forward shift of the threshold voltage of the first transistor T1 may also result in the increasing of the driving current, and the increased driving current may result in that the display brightness is higher than that before the reliability test. Therefore, in the example embodiment, by providing the fourth auxiliary portion B4 on the auxiliary layer BSM, it is possible to maintain the stability of the first transistor T1, thus further avoiding the problem of display defect of the display panel before and after the high-temperature reliability test, such as brighter display.

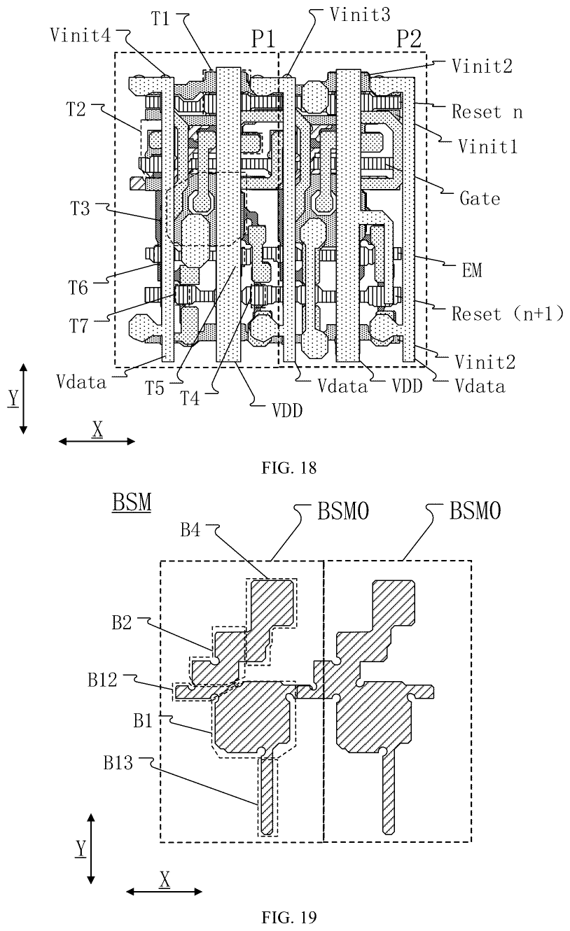

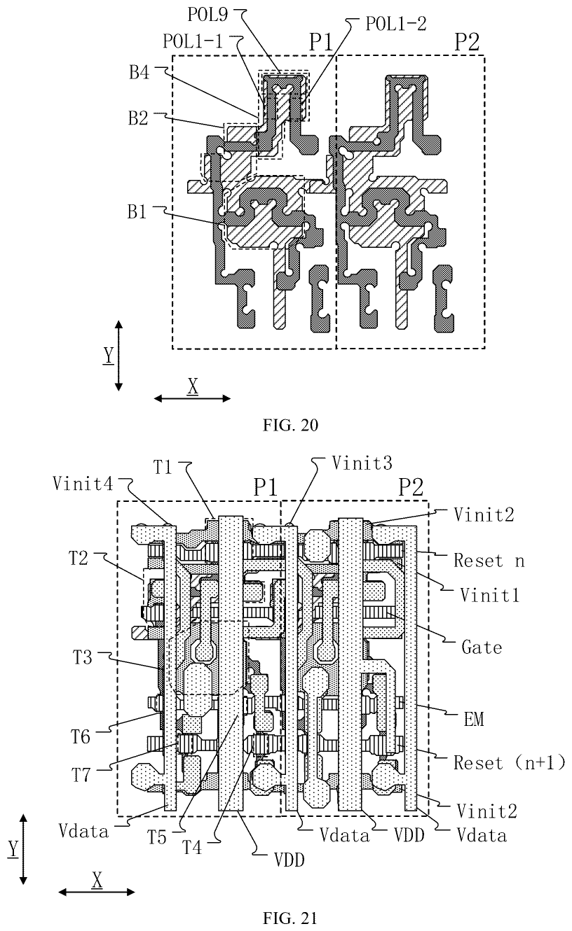

Based on the foregoing embodiment, FIG. 18 is a structural layout of a display panel according to another embodiment of the present disclosure, FIG. 19 is a structural layout of the auxiliary layer in FIG. 18, and FIG. 20 is a stacked layout of the auxiliary layer and the active layer in FIG. 18. The active layer Poly to the second source-drain metal layer SD2 in the display panel shown in FIG. 18 are provided with all features corresponding to the active layer Poly to the second source-drain metal layer SD2 in the display panel in FIG. 3.

As shown in FIG. 18 to FIG. 20, in some embodiments, the difference from the layout structure shown in FIG. 14 is that, the orthographic projection of the fourth auxiliary portion B4 on the base substrate may further cover the orthographic projection of the ninth active portion POL9 on the base substrate. As described above, the first transistor T1 is a double-channel transistor, and the characteristic change of the first transistor T1 may result in a change in the driving current. In the example embodiment, the orthographic projection of the ninth active portion POL9 on the base substrate is located within the orthographic projection of the fourth auxiliary portion B4 on the base substrate, so that the fourth auxiliary portion B4 also blocks the ninth active portion POL9, that is, the fourth auxiliary portion B4 also blocks the conductorization structure T1M between the two channels of the first transistor T1. Therefore, the fourth auxiliary portion B4 may further block the free charge in the bottom layer from entering the conductorization structure TIM between the two channels of the first transistor T1, which is beneficial to maintaining the stability of the characteristics of the first transistor T1 by further avoiding the threshold voltage drift of the first transistor T1, thus avoiding the defect problem of brighter display of the display panel before and after the high-temperature reliability test and before and after the copper bar friction test.

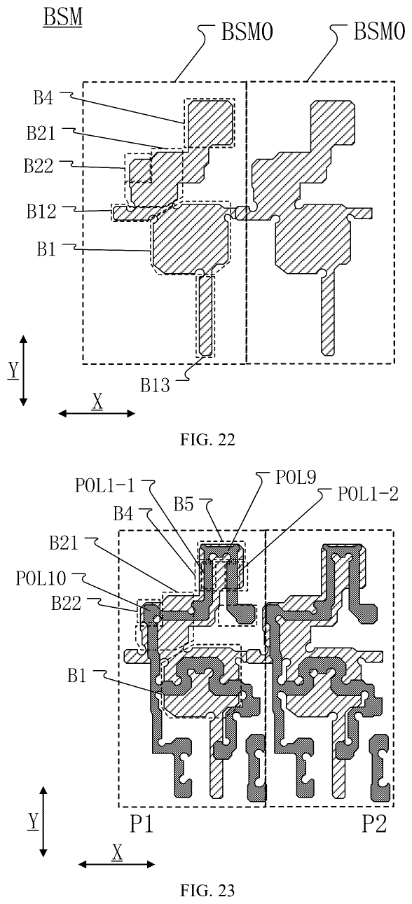

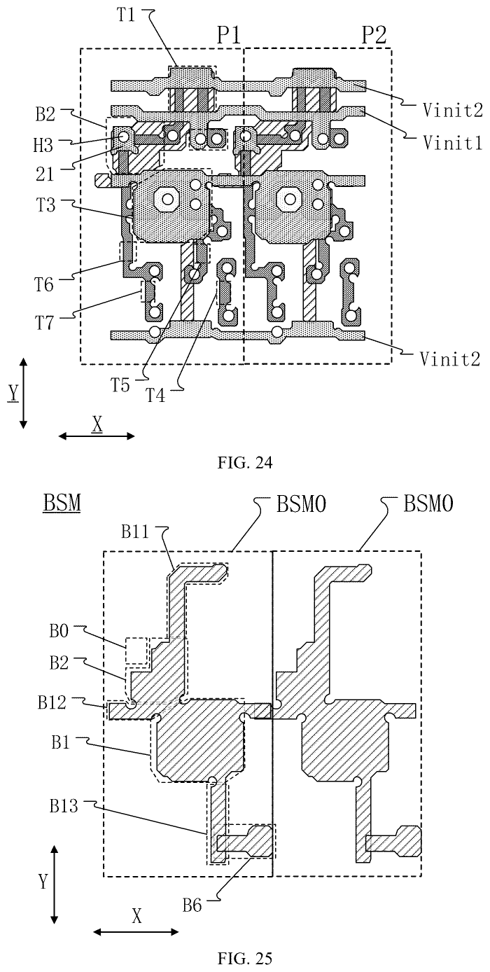

Based on the above embodiments, FIG. 21 is a structural layout of a display panel according to another embodiment of the present disclosure; FIG. 22 is a structural layout of the auxiliary layer in FIG. 21; FIG. 23 is a stacked layout of the auxiliary layer and the active layer in FIG. 21; and FIG. 24 is a stacked layout of the auxiliary layer, the active layer and the second conductive layer in FIG. 21. The active layer Poly to the second source-drain metal layer SD2 in the display panel shown in FIG. 21 are provided with all features corresponding to the active layer Poly to the second source-drain metal layer SD2 in the display panel in FIG. 3.

As shown in FIG. 21 and FIG. 22, in the example embodiment, the second auxiliary portion B2 may include both the first auxiliary sub-portion B21 and the second auxiliary sub-portion B22, and the auxiliary unit BSM0 may further include a fourth auxiliary portion B4. That is, the auxiliary unit BSM0 blocks the first transistor T1 while blocking the conductorization structure T2M between the two channels of the second transistor T2. Similar to the layout structure shown in FIG. 10, the second auxiliary sub-portion B22 is connected to the second auxiliary portion B2, and the orthographic projection of the second auxiliary sub-portion B22 on the base substrate covers the orthographic projection of the tenth active portion POL10 on the base substrate, that is, the second auxiliary sub-portion B22 is also provided below the conductorization structure T2M between the two channels of the second transistor T2 for charge blocking. Furthermore, as shown in FIG. 24, the orthographic projection of the second auxiliary sub-portion B22 on the base substrate further covers the orthographic projection of the third via hole H3 on the base substrate, that is, the region covered by the orthographic projection of the third via hole H3 on the base substrate is completely located within the region covered by the orthographic projection of the second auxiliary sub-portion B22 on the base substrate. Therefore, the second sub-auxiliary portion B22 in the example embodiment may have the same function as the second sub-auxiliary portion B22 in the layout structure shown in FIG. 10.

In addition, as shown in FIG. 21 and FIG. 22, the fourth auxiliary portion B4 in the example embodiment is connected to the second auxiliary portion B2, and the orthographic projection of the fourth auxiliary portion B4 on the base substrate may cover the orthographic projection of the first active portion POL1 on the base substrate. That is, the fourth auxiliary portion B4 may have the layout structure as shown in FIG. 14, and correspondingly may also have the beneficial effect of the fourth auxiliary portion B4 in the layout structure shown in FIG. 14. Alternatively, the orthographic projection of the fourth auxiliary portion B4 on the base substrate may cover both the orthographic projection of the first active portion POL1 on the base substrate and the orthographic projection of the ninth active portion POL9 on the base substrate. That is, the fourth auxiliary portion B4 may have the layout structure as shown in FIG. 18, and correspondingly may have the beneficial effect of the fourth auxiliary portion B4 in the layout structure shown in FIG. 18. Details are not described here again.

In addition, on the basis of the foregoing embodiments, the auxiliary unit BSM0 may further include a sixth auxiliary portion B6, the sixth auxiliary portion B6 is connected to the third connecting portion B13, the sixth auxiliary portion B6 is provided corresponding to the fourth active portion POL4, and the orthographic projection of the sixth auxiliary portion B6 on the base substrate extends along the row direction and covers the orthographic projection of the fourth active portion POL4 on the base substrate.

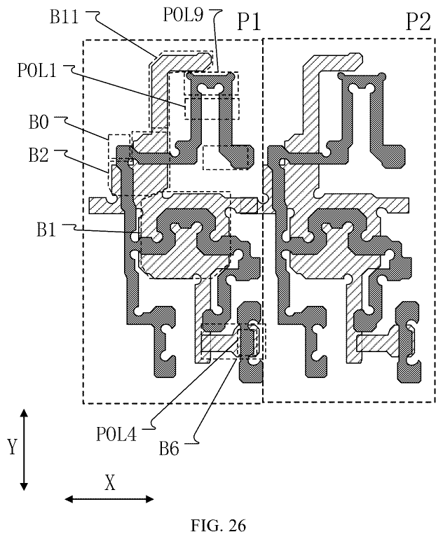

For example, in some embodiments, the auxiliary unit BSM0 may form the layout structure as shown in FIG. 25 based on the layout structure as shown in FIG. 4, and the active layer Poly to the second source-drain metal layer SD2 are provided with all features corresponding to the active layer Poly to the second source-drain metal layer SD2 in the display panel in FIG. 3. The stacked layout of the auxiliary layer BSM and the active layer Poly is as shown in FIG. 26.

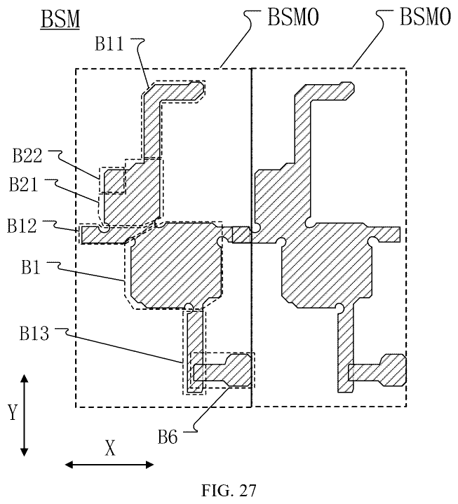

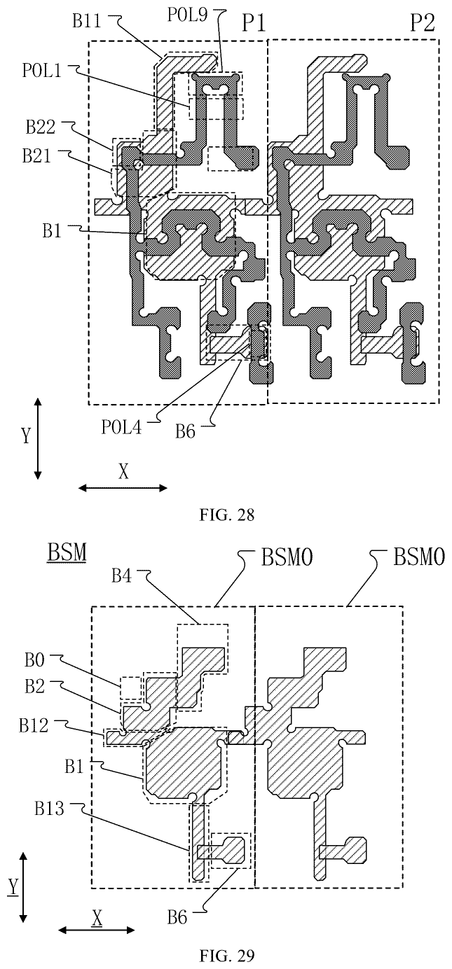

In some other embodiments, the auxiliary unit BSM0 may further form the layout structure as shown in FIG. 27 based on the layout structure as shown in FIG. 11, and the active layer Poly to the second source-drain metal layer SD2 are provided with all features corresponding to the active layer Poly to the second source-drain metal layer SD2 in the display panel in FIG. 10. The stacked layout of the auxiliary layer BSM and the active layer Poly is as shown in FIG. 28.

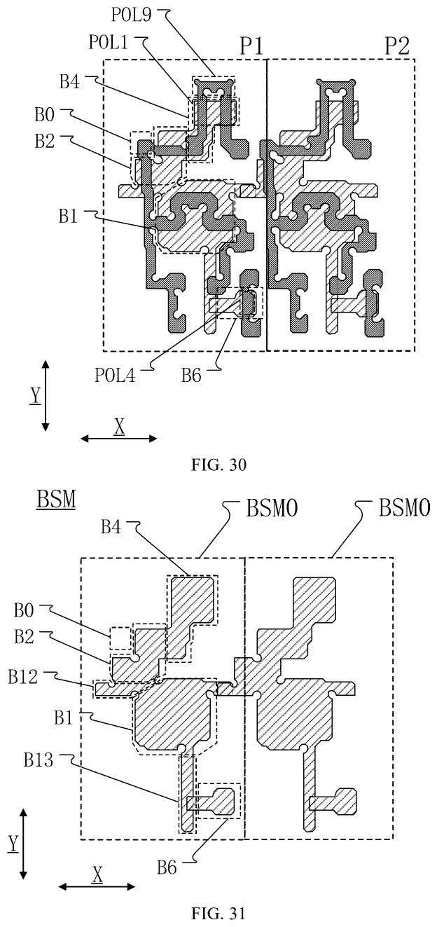

In some other embodiments, the auxiliary unit BSM0 may further form the layout structure as shown in FIG. 29 based on the layout structure as shown in FIG. 15, and the active layer Poly to the second source-drain metal layer SD2 are provided with all features corresponding to the active layer Poly to the second source-drain metal layer SD2 in the display panel in FIG. 14. The stacked layout of the auxiliary layer BSM and the active layer Poly is as shown in FIG. 30.

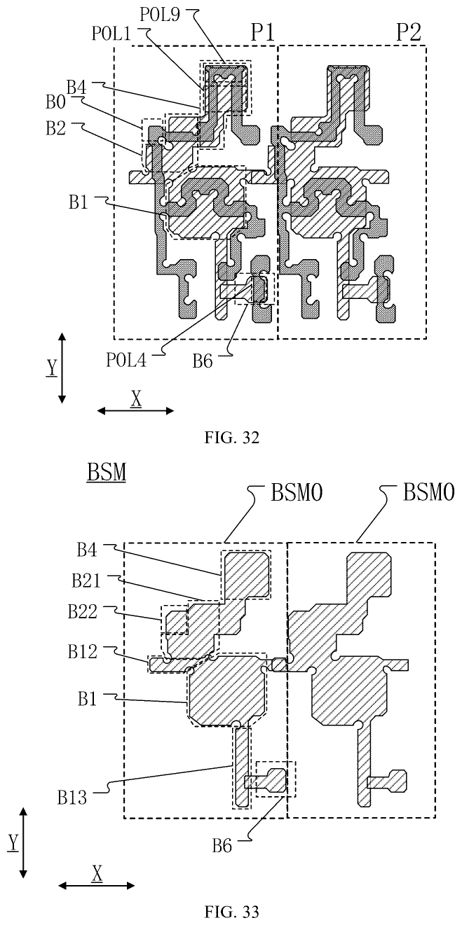

In still other embodiments, the auxiliary unit BSM0 may further form the layout structure as shown in FIG. 31 based on the layout structure as shown in FIG. 19, and the active layer Poly to the second source-drain metal layer SD2 are provided with all features corresponding to the active layer Poly to the second source-drain metal layer SD2 in the display panel in FIG. 18. The stacked layout of the auxiliary layer BSM and the active layer Poly is as shown in FIG. 32.

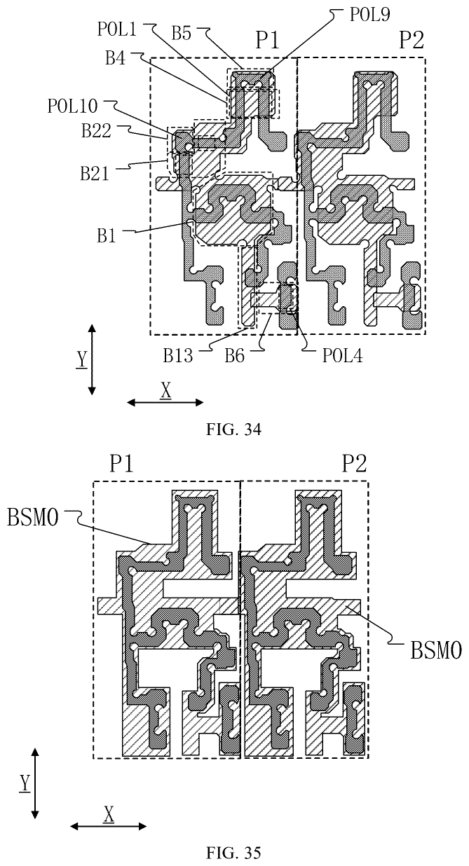

In still some other embodiments, the auxiliary unit BSM0 may further form the layout structure as shown in FIG. 33 based on the layout structure as shown in FIG. 22, and the active layer Poly to the second source-drain metal layer SD2 are provided with all features corresponding to the active layer Poly to the second source-drain metal layer SD2 in the display panel in FIG. 21. The stacked layout of the auxiliary layer BSM and the active layer Poly is as shown in FIG. 34.

Of course, in other embodiments of the present disclosure, the orthographic projection of the auxiliary unit BSM0 on the base substrate may also cover the orthographic projections of all transistors in the corresponding pixel driving circuit on the base substrate. For example, as shown in FIG. 35, the orthographic projection shape of the auxiliary unit BSM0 in the auxiliary layer BSM on the base substrate may be similar to the orthographic projection shape of the active layer structure in the corresponding pixel driving circuit on the base substrate, and the orthographic projection of the active layer structure of a pixel driving circuit on the base substrate is located within the orthographic projection of the auxiliary unit BSM0 at the corresponding position on the base substrate, so that the auxiliary unit BSM0 can form a barrier for all the transistors below the corresponding pixel driving circuit, thus further improving the barrier effect on the free charge.

In the present disclosure, the display panel may further include a first conductive layer Gate1, a second conductive layer Gate2, a first source-drain metal layer SD1, and a second source-drain metal layer SD2 that are stacked and provided on a side of the active layer Poly away from the base substrate. The first conductive layer Gate1 may be a first gate metal layer, the second conductive layer Gate2 may be a second gate metal layer, and an insulating layer may be provided between two adjacent conductive layers. For example, a first gate insulating layer may be provided between the first conductive layer Gate1 and the active layer Poly, a second gate insulating layer may be provided between the second conductive layer Gate2 and the first conductive layer Gate1, an interlayer dielectric layer may be provided between the first source-drain metal layer SD1 and the second conductive layer Gate2, and a passivation layer and a planarization layer etc., may be provided between the second source-drain metal layer SD2 and the first source-drain metal layer SD1.

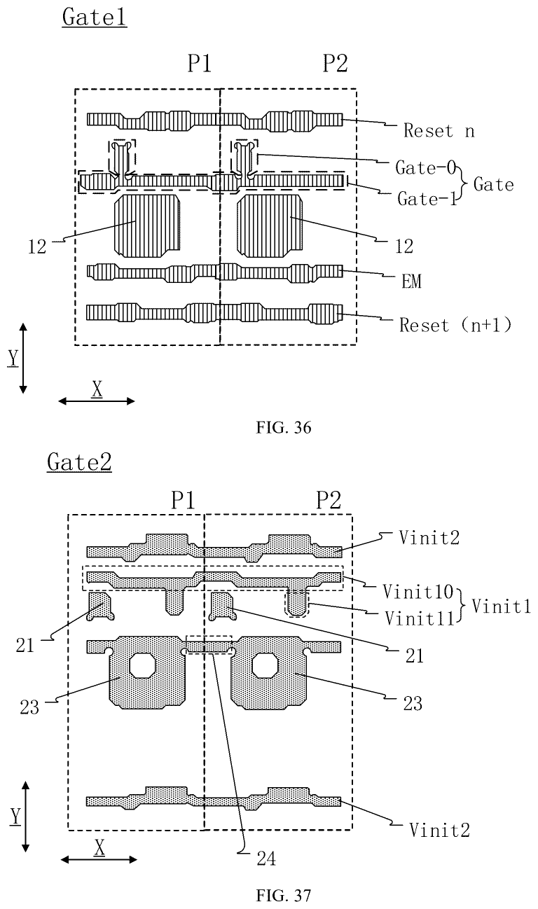

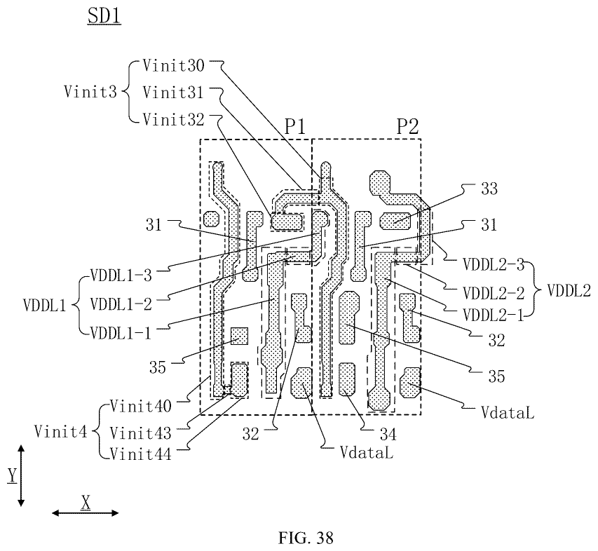

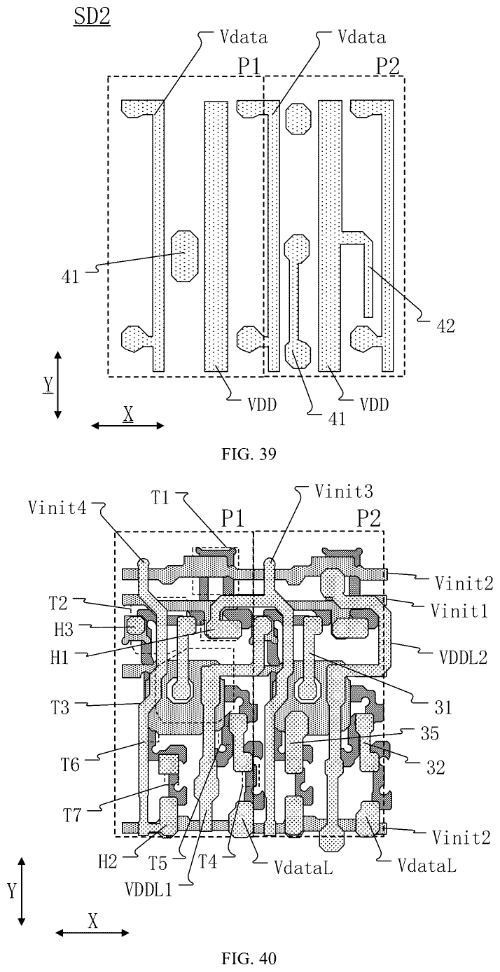

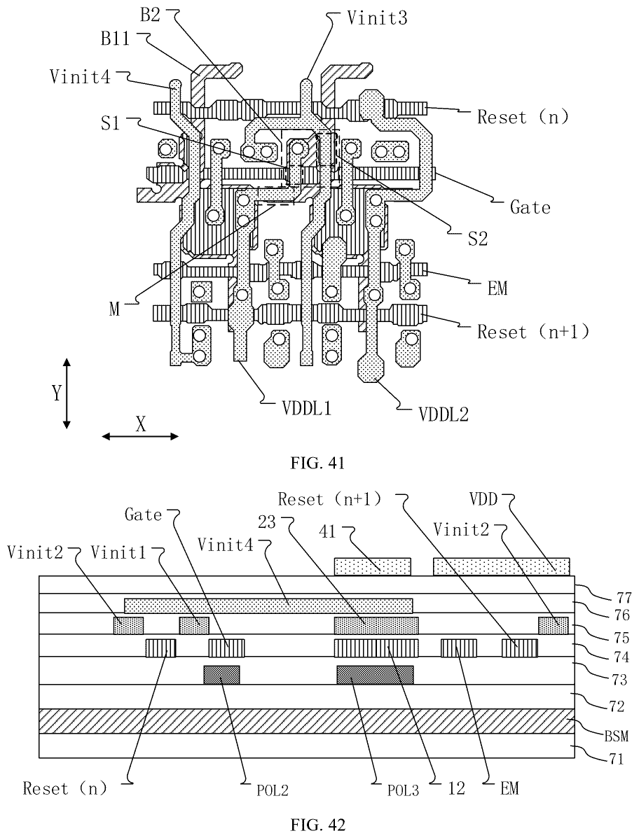

FIG. 36 is a structural layout of the first conductive layer in FIG. 3; FIG. 37 is a structural layout of the second conductive layer in FIG. 3; FIG. 38 is a structural layout of the first source-drain metal layer in FIG. 3; FIG. 39 is a structural layout of the second source-drain metal layer in FIG. 3; FIG. 40 is a stacked layout of the auxiliary layer, the active layer and the first source-drain metal layer in FIG. 3; and FIG. 41 is a stacked layout of the auxiliary layer, the first conductive layer and the first source-drain metal layer in FIG. 3.

As shown in FIG. 3 and FIG. 36, in some embodiments, the first conductive layer Gate1 may include a second conductive block 12, a first reset signal line Reset (n), a gate signal line Gate, an enable signal line EM, and a second reset signal line Rest (n+1). Orthographic projections of the first reset signal line Reset (n), the gate signal line Gate, the second conductive block 12, the enable signal line EM, and the second reset signal line Reset (n+1) on the base substrate may all extend along the row direction and are distributed at intervals along the column direction. The first reset signal line Reset (n) and the gate signal line Gate are located on the same side of the second conductive block 12, and the enable signal line EM and the second reset signal line Reset (n+1) are located on the other side of the second conductive block 12.

The orthographic projection of the second conductive block 12 on the base substrate may cover the orthographic projection of the third active portion POL3 on the base substrate, and the second conductive block 12 may be configured to form the gate of the driving transistor T3 and the first electrode of the storage capacitor Cst. In this way, in the layout structure, the first reset signal line Reset (n) and the gate signal line Gate are located on the same side of the driving transistor T3, and the enable signal line EM and the second reset signal line Reset (n+1) are located on the other side of the driving transistor T3.

The first reset signal line Reset (n) may be configured to provide the first reset signal end in FIG. 1, and the orthographic projection of the first reset signal line Reset (n) on the base substrate may cover the orthographic projection of the first active sub-portion POL1-1 on the base substrate and the orthographic projection of the second active sub-portion POL1-2 on the base substrate, so that a partial structure of the first reset signal line Reset (n) is configured to form the gate of the first transistor T1, and the first transistor T1 forms a double-gate structure.

The gate signal line Gate may be configured to provide the gate signal end in FIG. 1, the orthographic projection of the gate signal line Gate on the base substrate may cover the orthographic projection of the second active portion POL2 on the base substrate, and a partial structure of the gate signal line Gate forms the gate of the second transistor T2. In the example embodiment, the second active portion POL2 in the active layer Poly may include a third active sub-portion POL2-3 and a fourth active sub-portion POL2-4, that is, the second transistor T2 includes two channel regions. The gate signal line Gate may include a main extension portion Gate-0 and an additional portion Gate-1, the orthographic projection of the main extension portion Gate-0 on the base substrate may cover the orthographic projection of the third active sub-portion POL2-3 on the base substrate, and the orthographic projection of the additional portion Gate-1 on the base substrate may cover the orthographic projection of the fourth active sub-portion POL2-4 on the base substrate, so that the second transistor T2 forms a double-gate structure.

The enable signal line EM may be configured to provide the enable signal end in FIG. 1, the orthographic projection of the enable signal line EM on the base substrate may respectively cover the orthographic projection of the fifth active portion POL5 on the base substrate and the orthographic projection of the sixth active portion POL6 on the base substrate, a partial structure of the enable signal line EM may be configured to form the gate of the fifth transistor T5, and a partial structure of the enable signal line EM may be configured to form the gate of the sixth transistor T6.

The second reset signal line Reset (n+1) may be configured to provide the second reset signal end in FIG. 1, the orthographic projection of the second reset signal line Reset (n+1) on the base substrate may cover the orthographic projection of the seventh active portion POL7 on the base substrate, and a partial structure of the second reset signal line Reset (n+1) may be configured to form the gate of the seventh transistor T7.

In the display panel of the present disclosure, the first conductive layer Gate1 may be used as a mask to perform conductorization treatment the active layer Poly, that is, the active layer Poly covered by the first conductive layer Gate1 forms the channel region of the transistor, and the region not covered by the first conductive layer Gate1 forms a conductorization structure.

As shown in FIG. 3 and FIG. 37, in some embodiments, the second conductive layer Gate2 may include a third conductive block 23 as well as a first initialization signal line Vinit1 and a second initialization signal line Vinit2 extending along the row direction and located on the same side of the third conductive block 23. The orthographic projection of the third conductive block 23 on the base substrate may be located on an orthographic projection of the second conductive block 12 on the base substrate, and the third conductive block 23 may be configured to form the second electrode of the storage capacitor Cst.

As shown in FIG. 37, in some embodiments, the third conductive block 23 may be connected to the power transfer line VDDL located in the first source-drain metal layer SD1 through a via hole, and then is connected to the first power line VDD in the second source-drain metal layer SD2 through the power transfer line VDDL, so that the third conductive block 23 is connected to the first power line VDD.

As shown in FIG. 37, in some embodiments, two third conductive blocks 23 adjacent in the row direction are connected by a connecting line 24, so that the first power line VDD forms a grid structure in a crisscross manner through the third conductive block 23 extending laterally. The first power line VDD of the grid structure may reduce the impedance of the first power line VDD, thus reducing the RC load of the first power line VDD, and reducing the power consumption of the display panel.

As shown in FIG. 37, in some embodiments, the first initialization signal line Vinit1 may include a main signal line Vinit10 and an auxiliary portion Vinit11, the main signal line Vinit10 may extend along the row direction, the auxiliary portion Vinit11 may be connected to the side of the main signal line in the column direction, and the auxiliary portion Vinit11 may be connected to the third initialization signal line Vinit3 located in the first source-drain metal layer SD1 through a via hole, so as to connect the first initialization signal line Vinit1 to the twelfth active portion POL12 in the active layer Poly through the third initialization signal line Vinit3, thus connecting the first electrode of the first transistor T1 to the first initialization signal line Vinit1. Meanwhile, the third initialization signal line Vinit3 extends along the column direction and is connected to the first initialization signal line Vinit1 in each row, thus the first initialization signal line Vinit1 forms a grid structure in a crisscross manner. In this way, on one hand, the impedance of the first initialization signal line Vinit1 may be reduced, the RC load of the first initialization signal line Vinit1 may be reduced, and the power consumption may be reduced. On the other hand, in the non-display region, the third initialization signal line Vinit3 is connected to the auxiliary layer BSM through a via hole, so that the first initialization signal line Vinit3 may be configured to provide the first signal for the auxiliary layer BSM through the connection of the third initialization signal line Vinit3, thus the display panel keeps the display characteristic stable before and after the high-temperature reliability test and the copper bar friction test. Certainly, in other embodiments, in the non-display region, the first initialization signal line Vinit1 may be directly connected to the auxiliary layer BSM through a via hole; for example, the first initialization signal line Vinit1 may form a ring in the non-display region, and then may be connected to the auxiliary layer BSM through a via hole.

As shown in FIG. 37, in some embodiments, the second initialization signal line Vinit2 may be connected to the fourth initialization signal line Vinit4 located in the first source-drain metal layer SD1 through the second via hole H2, so as to be connected to the nineteenth active part POL19 in the active layer Poly through the fourth initialization signal line Vinit4, thus connecting the first electrode of the seventh transistor T7 to the second initialization signal line Vinit2. Similarly, on one hand, the second initialization signal line Vinit2 forms a grid structure in a crisscross manner through the fourth initialization signal line Vinit4; on the other hand, in the non-display region, the fourth initialization signal line Vinit4 may be connected to the auxiliary layer BSM, providing the first signal for the auxiliary layer BSM. In the same way, in other embodiments, in the non-display region, the second initialization signal line Vinit2 may be directly connected to the auxiliary layer BSM through the via hole, and details are not described here again.

As shown in FIG. 37, in some embodiments, the second conductive layer Gate2 may further include a first conductive block 21, the orthographic projection of the first conductive block 21 on the base substrate may be located on an orthographic projection of the tenth active portion POL10 on the base substrate, that is, the first conductive block 21 may cover the conductorization structure between the two channel regions of the second transistor T2. In addition, the first conductive block 21 may be connected to the power transfer line VDDL located in the first source-drain metal layer SD1 through the third via hole H3, so as to connect the first conductive block 21 to the first power line VDD in the second source-drain metal layer SD2 through the power transfer line VDDL. In this way, the first conductive block 21 has a voltage stabilization effect on the tenth active portion POL 10, that is, the first conductive block 21 may be used to perform voltage stabilization on the conductorization structure connected to the two channel regions of the second transistor T2, so that the leakage of the second transistor T2 may be reduced, and the interference of the alternating voltage on the data signal line Vdata to the tenth active portion POL10 may be reduced, thus reducing the voltage fluctuation of driving the transistor T3 in the light-emitting stage of the pixel driving circuit, so as to improve the screen quality. It should be noted that, the third via hole H3 here refers to a via hole formed in the insulating layer of the first conductive block 21 and the power transfer line VDDL, that is, the via hole through which the first conductive block 21 is connected to the power transfer line VDDL. The power transfer line VDDL may be connected to the first power line VDD in the second source-drain metal layer SD2 at other positions through the via hole, that is, the position of the via hole through which the first power line VDD is connected to the power transfer line VDDL may be different from the position of the third via hole H3. Certainly, in other embodiments, the first power line VDD may also be connected to the power transfer line VDDL at a position corresponding to the third via hole H3.

In addition, as shown in FIG. 3 and FIG. 37, in some embodiments, due to the presence of the first conductive block 21, it is needed to form a third via hole H3 in the interlayer dielectric layer located on the second conductive layer Gate2, so as to be connected to the power transfer line VDDL in the first source-drain meta layer SD1 through the third via hole H3. On this basis, the orthographic projection of the auxiliary unit BSM0 in the auxiliary layer BSM on the base substrate may also cover the orthographic projection of the third via hole H3 on the base substrate. Specifically, as shown in FIG. 37 and FIG. 40, the second auxiliary portion B2 in the auxiliary layer BSM may include the first auxiliary sub-portion B21 and the second auxiliary sub-portion B22, an the orthographic projection of the second auxiliary sub-portion B22 on the base substrate may cover the orthographic projection of the first conductive block 21 on the base substrate and the orthographic projection of the third via hole H3 on the base substrate, thus avoiding that it is not flat below the via hole in the interlayer dielectric layer caused by process fluctuations. It should be known that when it is not flat below the via hole, it may result in deformation of the via hole and result in display defects such as the display stripe between different sub-pixels. Therefore, in the example embodiment, by completely covering the third via hole H3 through the auxiliary layer BSM, the third via hole H3 may be prevented from deforming, thus avoiding the defect of the display stripe caused by deformation of the via hole on the interlayer dielectric layer.

As shown in FIG. 3, FIG. 38 and FIG. 40, in some embodiments, the first source-drain metal layer SD1 may include a third initialization signal line Vinit3 and a fourth initialization signal line Vinit4, both the third initialization signal line Vinit3 and the fourth initialization signal line Vinit4 may extend along the column direction. The third initialization signal line Vinit3 may be connected to the first initialization signal line Vinit1 through the first via hole H1 to form a parallel structure to the first initialization signal line Vinit1, which may thus further extend to the non-display region through the third initialization signal line Vinit3 extending the column direction and may be connected to the auxiliary layer BSM for providing the first signal for the auxiliary layer BSM. The fourth initialization signal line Vinit4 may be connected to the second initialization signal line Vinit2 through the second via hole to form a parallel structure to the second initialization signal line Vinit2, which may thus further extend to the non-display region through the fourth initialization signal line Vinit4 and may be connected to the auxiliary layer BSM for providing the first signal for the auxiliary layer BSM in the example embodiment. That is, in the example embodiment, the first signal may be provided for the auxiliary layer BSM through the first initialization signal line Vinit1 or the first signal may be provided for the auxiliary layer BSM through the second initialization signal line Vinit2.

As shown in FIG. 38 and FIG. 40, in some embodiments, the display panel may include a first pixel column P1 and a second pixel column P2 that are sequentially and alternately distributed along the row direction, the third initialization signal line Vinit3 may be located in the second pixel column P2, the fourth initialization signal line Vinit4 may be located in the first pixel column P1, and the first via hole H1 and the second via hole H2 are both located in the first pixel column P1. In addition, in the example embodiment, the pixel driving circuit located in the first pixel column P1 may be a first pixel driving circuit, and the pixel driving circuit located in the second pixel column P2 may be a second pixel driving circuit. The display panel may include a plurality of repeating units distributed in an array along the row and the column direction. A repeating unit includes a first pixel driving circuit and a second pixel driving circuit adjacent to the first pixel driving circuit along the row direction. It should be understood that a certain structure A located in a certain pixel column B described in the present disclosure may be understood as that the orthographic projection of the structure A on the base substrate is located within the region where the pixel column B is located.

For example, as shown in FIG. 38, the third initialization signal line Vinit3 may include a first main body portion Vinit30, a first extension portion Vinit31 and a second extension portion Vinit32. The first main body portion Vinit30 may be located in the second pixel column P2, and the first extension portion Vinit31 may be connected between the first main body portion Vinit30 and the second extension portion Vinit32. One end of the second extension portion Vinit32 is connected to the first initialization signal line Vinit1 through the first via hole H1, and the other end is connected to the twelfth active portion POL12 through another via hole. Therefore, the third initialization signal line Vinit3 is connected to the first initialization signal line Vinit1 on one hand, and is also connected to the first electrode of the first transistor T1 in the first pixel column P1 on the other hand. Meanwhile, the first source-drain metal layer SD1 may further include a third bridge portion 33, and the third bridge portion 33 is located in the second pixel column P2 to connect the first electrode of the first transistor T1 to the first initialization signal line Vinit1 in the second pixel column P2.

As shown in FIG. 38, the fourth initialization signal line Vinit4 may include a second main body portion Vinit40, a third extension portion Vinit43, and a fourth extension portion Vinit44. The third extension portion Vinit43 is connected between the second main body portion Vinit40 and the fourth extension portion Vinit44. One end of the fourth extension portion Vinit44 is connected to the second initialization signal line Vinit2 through the second via hole H2, and the other end is connected to the nineteenth active portion POL19 through another via hole. Therefore, the fourth initialization signal line Vinit4 is connected to the second initialization signal line Vinit2 on one hand, and is also connected to the first electrode of the seventh transistor T7 in the first pixel column P1 on the other hand. Meanwhile, the first source-drain metal layer SD1 may further include a fourth bridge portion 34, the fourth bridge portion 34 is located in the second pixel column P2, and the orthographic projection of the fourth bridge portion 34 on the base substrate may extend along the column direction. The fourth bridge portion 34 may be connected to the nineteenth active portion POL19 and the second initialization signal line Vinit2 through via holes, respectively, so that the first electrode of the seventh transistor T7 is connected to the second initialization signal line Vinit2 through the fourth bridge portion 34 in the second pixel column P2.

It can be seen that in the example embodiment, in the same repeating unit, the first initialization signal line Vinit1 is connected to the first electrode of the first transistor T1 in the first pixel driving circuit through the third initialization signal line Vinit3, and is connected to the first electrode of the first transistor T1 in the second pixel driving circuit through the third bridge portion 33. The second initialization signal line Vinit2 is connected to the first electrode of the seventh transistor T7 in the first pixel driving circuit through the fourth initialization signal line Vinit4, and is connected to the first electrode of the seventh transistor T7 in the second pixel driving circuit through the fourth bridge portion 34.

As shown in FIG. 38 and FIG. 40, in some embodiments, the first source-drain metal layer SD1 may further include a power transfer line VDDL. The power transfer line VDDL may include a first transfer portion VDDL-1, a second transfer portion VDDL-2, and a third transfer portion VDDL-3. For example, the first power transfer line VDDL1 may include three transfer portions of the first transfer portion VDDL1-1, the second transfer portion VDDL1-2, and the third transfer portion VDDL1-3; and the second power transfer line VDDL2 may include three transfer portions of the first transfer portion VDDL2-1, the second transfer portion VDDL2-2, and the third transfer portion VDDL2-3. The orthographic projection of the first transfer portion VDDL-1 on the base substrate and the orthographic projection of the third transfer portion VDDL-3 on the base substrate both extend along the column direction, the orthographic projection of the second transfer portion VDDL-2 on the base substrate extends along the row direction, and the first transfer portion VDDL-1 and the third transfer portion VDDL-3 are connected through the second transfer portion VDDL-2. That is, the power transfer line VDDL is provided to be bent, a partial structure is located in the present pixel driving circuit, and a partial structure is located in the pixel driving circuit adjacent in the row direction. Therefore, the power transfer line VDDL is respectively connected to the third conductive block 23 and the first power line VDD through the first transfer portion VDDL-1 located in the present pixel driving circuit, and is connected to the first conductive block 21 in the adjacent pixel driving circuit through the third transfer portion VDDL-3 located in the adjacent pixel driving circuit, so that the third conductive block 23 in the present pixel driving circuit and the first conductive block 21 in the adjacent pixel column are connected to the first power line VDD in the second source-drain metal layer SD2.

Furthermore, as described above, the display panel may include a first pixel column P1 and a second pixel column P2 which are alternately distributed along the row direction. On this basis, the power transfer line VDDL1 may include a first power transfer line VDDL1 and a second power transfer line VDDL2, where the first power transfer line VDDL1 is located in the first pixel column P1, the second power transfer line VDDL2 is located in the second pixel column P2. The first power transfer line VDDL 1 in the first pixel column P1 may be connected to the third conductive block 23 in the second conductive layer Gate2 through a via hole, and may be connected to the first power line VDD in the second source-drain metal layer SD2 through a via hole, thus connecting the second electrode of the storage capacitor Cst to the first power line VDD. In addition, the first power line VDDL1 is bent in a direction close to the second pixel column P2 after crossing the third conductive block 23 in the first pixel column P1, so that the first power line VDDL1 in the first pixel column P1 is connected to the first conductive block 21 in the second pixel column P2 in the same repeating unit through the via hole, thus the first conductive block 21 in the second pixel column P2 in the same repeating unit is connected to the first power line VDD.

The second power transfer line VDDL2 in the second pixel column P2 may be connected to the third conductive block 23 in the second conductive layer Gate2 through a via hole, and may be connected to the first power line VDD in the second source-drain metal layer SD2 through a via hole, so as to connect the second electrode of the storage capacitor Cst in the second pixel column to the first power line VDD. In addition, the second power transfer line VDDL2 is bent in a direction close to another repeating unit adjacent in the row direction after crossing the third conductive block 23 in the second pixel column P2, so as to be connected to the first conductive block 21 in the first pixel column P1 in another repeating unit adjacent in the row direction through a via hole, thus connecting the first conductive block 21 in the first pixel column P1 in the repeating unit adjacent in the row direction to the first power line VDD.

Furthermore, as shown in FIG. 38, in the example embodiment, the extension length of the orthographic projection of the second power transfer line VDDL2 on the base substrate along the column direction is greater than the extension length of the orthographic projection of the first power transfer line VDDL1 on the base substrate along the column direction. As can be seen from FIG. 38, the first power transfer line VDDL1 is an isolated structure, that is, the first power transfer lines VDDL1 located in different pixel driving circuits in the same column are not connected to each other. The second power transfer line VDDL2 is of a continuous structure, that is, the second power transfer lines VDDL2 located in different pixel driving circuits in the same column are connected to each other to form a continuous structure. Therefore, the extension length of the orthographic projection of the second power transfer line VDDL2 on the base substrate along the column direction is greater than the extension length of the orthographic projection of the first power transfer line VDDL1 on the base substrate along the column direction. In addition, in the non-display region of the display panel, the second power transfer line VDDL2 may be connected to the auxiliary layer BSM through the via hole, to provide the first signal for the auxiliary layer BSM. As described above, the power transfer line in a pixel driving circuit may include a plurality of transfer portions, orthographic projections of partial transfer portions extend along the column direction, and orthographic projections of partial transfer portions extend along the row direction. Therefore, the extension length of the orthographic projection of a certain power transfer line on the base substrate along the column direction may be understood as a sum of the extension lengths of various portions extending along the column direction in the orthographic projection of the power transfer line on the base substrate. In this way, the extension length of the second power transfer line VDDL2 along the column direction being greater than the extension length of the first power transfer line VDDL1 along the column direction is that, the sum of the extension lengths of the various portions extending along the column direction in the orthographic projection of the second power transfer line VDDL2 is greater than the sum of the extension lengths of the various portions extending along the column direction in the orthographic projection of the first power transfer line VDDL1.

As shown in FIG. 38 and FIG. 41, in the example embodiment, the orthographic projection of the second transfer portion VDDL-2 on the base substrate at least partially overlaps with the orthographic projection of the second connecting portion B12 in the auxiliary layer BSM on the base substrate. Taking the first power transfer line VDDL1 as an example, as shown in FIG. 41, at the dotted frame M in the figure, the orthographic projection of the second transfer portion VDDL-2 of the first power transfer line VDDL1 on the base substrate may partially overlap with the orthographic projection of the second connecting portion B12 on the base substrate, and the second connecting portion B12 is located below the second transfer portion VDDL-2 of the first power transfer line VDDL1. Through the overlapping arrangement of the second transfer portion VDDL-2 and the second connecting portion B12, the total space occupied by wiring at this position in the layout may be saved, and the saved space may be used to improve the light transmittance.

In addition, the orthographic projection of the connecting line 24 in the second conductive layer Gate2 for connecting the third conductive blocks 23 in the two adjacent pixel driving circuits may be located within the orthographic projection of the second transfer portion VDDL-2 on the base substrate. In this way, the second connecting portion B12 in the auxiliary layer BSM, the connecting line 24 in the second conductive layer Gate2, and the second transfer portion VDDL-2 in the first source-drain metal layer SD1 are provided at this position in an overlapping manner. In addition, the connecting line 24 in the second conductive layer Gate2 is equipotential with the second transfer portion VDDL-2 in the first source-drain metal layer SD1, and signal crosstalk may not be formed, so that the space occupied by wiring at this position may be further saved through the overlapping arrangement of the three structures, and the light transmittance may be improved.

In some other embodiments, the orthographic projection of the second connecting portion B12 on the base substrate may further cover the orthographic projection of the second transfer portion VDDL-2 on the base substrate. That is, the second connecting portion B12 below completely blocks the connecting line 24 and the second transfer portion VDDL-2. Compared with the partial overlapping arrangement, the space occupied by wiring may be further saved, and the light transmittance is improved.

With reference to FIG. 38 and FIG. 41, in the example embodiment, there is provided a first overlapping portion S1 between the orthographic projection of the third transfer portion VDDL-3 located in the first source-drain metal layer SD1 and the orthographic projection of the main extension portion Gate-0 of the gate signal line Gate in the first conductive layer Gate1 on the base substrate; and, there is provided a second overlapping portion S2 between the orthographic projection of the third initialization signal line Vinit3 in the first source-drain metal layer SD1 and the orthographic projection of the additional portion Gate-1 of the gate signal line Gate in the first conductive layer Gate1 on the base substrate. The orthographic projection of the second auxiliary portion B2 on the base substrate may cover the first overlapping portion S1 and the second overlapping portion S2. That is, both the first overlapping portion S1 and the second overlapping portion S2 are located within the orthographic projection of the second auxiliary portion B2 on the base substrate, which is equivalent to that the second auxiliary portion B2 is enabled to cover the two overlapping portions by increasing the second auxiliary portion B2, so that the coupling capacitance of the auxiliary layer BSM at the positions of two channels of the second transistor T2 is consistent, thus eliminating display defect caused by the coupling capacitance difference.

As shown in FIG. 38 and FIG. 40, in some embodiments, the first source-drain metal layer SD1 may further include a first bridge portion 31. The first bridge portion 31 may extend along the column direction, and one end of the first bridge portion 31 may be connected to the eleventh active portion POL11 through a via hole, so as to be connected to the second electrode of the first transistor T1 and the first electrode of the second transistor T2. The other end of the first bridge portion 31 may be connected to the second conductive block 12 through a via hole, so as to connect to the gate of the driving transistor T3. In this way, the second electrode of the first transistor T1 and the first electrode of the second transistor T2 are connected to the gate of the driving transistor T3 through the first bridge portion 31.

As shown in FIG. 38 and FIG. 40, in some embodiments, the first source-drain metal layer SD1 may further include an anode transfer portion 35. One end of the anode transfer portion 35 may be connected to the eighteenth active portion POL18 through a via hole, so as to be connected the second electrode of the sixth transistor T6 and the second electrode of the seventh transistor T7; and the other end of the anode transfer portion 35 may be connected to the anode connecting portion 41 in the second source-drain metal layer SD2 through a via hole, so as to connect the second electrode of the sixth transistor T6 and the second electrode of the seventh transistor T7 to the anode of the light-emitting device through the anode connecting portion 41.

As shown in FIG. 3 and FIG. 39, in some embodiments, the second source-drain metal layer SD2 may include a first power line VDD and a data signal line Vdata. The orthographic projection of the first power line VDD on the base substrate and the orthographic projection of the data signal line Vdata on the base substrate may both extend along the column direction, where the first power line VDD may be configured to provide the first power end in FIG. 1, and the first power line VDD may be connected to the power transfer line VDDL in the first source-drain metal layer SD1 through a via hole, so as to be connected to the second electrode of the storage capacitor Cst and the first electrode of the fifth transistor T5 through the power transfer line VDDL. In addition, in the example embodiment, in the non-display region of the display panel, the first power line VDD may be connected to the auxiliary layer through a via hole to provide the first signal for the auxiliary layer. In some other embodiments of the present disclosure, the display panel may further include a second power line located in the first source-drain metal layer SD1; and in the non-display region, the second power line may be connected to the auxiliary layer through a via hole to provide the first signal for the auxiliary layer. For example, the second power line may be the power transfer line VDDL described in the foregoing embodiments, and the power transfer line VDDL is connected to the auxiliary layer through a via hole after extending to the non-display region.

It should be understood that in the present disclosure, the auxiliary layer may be alternatively connected to one of the first initialization signal line Vinit1, the second initialization signal line Vinit2, the first power line VDD, and the second power line. That is, in the present disclosure, the first signal may be provided for the auxiliary layer by the first initialization signal line Vinit1, the second initialization signal line Vinit2, the first power line VDD, or the second power line.

The data signal line Vdata may be configured to provide the data signal end in FIG. 1, and the data signal line Vdata may be connected to the data transfer portion VdataL in the first source-drain metal layer SD1 through a via hole, so as to be connected to the second electrode of the fourth transistor T4 through the data transfer portion VdataL.

As shown in FIG. 39, the second source-drain metal layer SD2 may further include an anode connecting portion 41 and an anode flat portion 42. The orthographic projection of the anode connecting portion 41 on the base substrate is located above the orthographic projection of the anode transfer portion 35 on the base substrate. The anode connecting portion 41 is located below the anode of the light-emitting device, and is connected to the anode. In this way, the anode of the light-emitting device may be connected to the second electrode of the seventh transistor T7 and the second electrode of the sixth transistor T6 through the anode connecting portion 41. Due to the presence of the anode connecting portion 41, there is a certain protrusion below the anode. On this basis, by additionally providing the anode flat portion 42 in the second source-drain metal layer SD2, the protrusion height of the anode connecting portion 41 may be balanced by using the anode flat portion 42, so as to avoid the situation that one side is higher and the other side is lower below the anode, thus avoiding that the anode is inclined, and ensuring normal display of the light-emitting device.

It should be understood that the terms “first”, “second”, “third”, or the like in the present disclosure are only used as labels, and are used to distinguish names of different structures, which do not limit the quantity of objects and do not indicate a sequential relationship either.

FIG. 41 is a cross-sectional view along the AA direction in FIG. 3. The display panel may further include a buffer layer 72, a first insulating layer 73, a second insulating layer 74, a first dielectric layer 75, a passivation layer 76, and a second dielectric layer 77, where the base substrate 71, the auxiliary layer BSM, the buffer layer 72, the active layer Poly, the first insulating layer 73, the first conductive layer Gate1, the second insulating layer 74, the second conductive layer Gate2, the first dielectric layer 75, the first source-drain metal layer SD1, the passivation layer 76, the second dielectric layer 77, and the second source-drain metal layer SD2 are stacked and provided in sequence. The first insulating layer 73 may be an organic insulating layer; the second insulating layer 74 may be silicon oxide; the first dielectric layer 75 and the second dielectric layer 77 may be silicon nitride layers; and the material of the passivation layer 76 and the buffer layer 72 may be silicon oxide, silicon nitride, or the like. The base substrate 71 may include a glass substrate, a barrier layer, and a polyimide layer stacked in sequence, and the barrier layer may be an inorganic material. The material of the first conductive layer Gate1 and the second conductive layer Gate2 may be one of molybdenum, aluminum, copper, titanium, and niobium, or an alloy, or a molybdenum/titanium alloy or laminated layer. The material of the first source-drain metal layer SD1 and the second source-drain metal layer SD2 may include a metal material, such as one of molybdenum, aluminum, copper, titanium, and niobium, an alloy, a molybdenum/titanium alloy or laminated layer, or a titanium/aluminum/titanium laminated layer, etc.

The present disclosure further provides a display apparatus, which may include the display panel described in any of the above embodiments.

Other embodiments of the present disclosure will be apparent to those skilled in the art from consideration of the description and practice of the present disclosure here. The present disclosure is intended to cover any variations, uses, or adaptations of the present disclosure following the general principles of present disclosure and including common general knowledge and conventional technical means in the art not disclosed in the present disclosure. It is intended that the description and examples should be considered as examples only, with a true scope and spirit of the present disclosure being indicated by the following claims.

1. A display panel, comprising a pixel driving circuit, wherein the pixel driving circuit comprises a second transistor and a driving transistor, a first electrode of the second transistor is connected to a gate of the driving transistor, and the display panel further comprises:
a base substrate;
an auxiliary layer, located on a side of the base substrate and connected to a first signal; and
an active layer, located on a side of the auxiliary layer away from the base substrate, and comprising:
a second active portion, configured to form a channel region of the second transistor; and
a third active portion, configured to form a channel region of the driving transistor;
wherein an orthographic projection of the auxiliary layer on the base substrate covers an orthographic projection of the second active portion on the base substrate and an orthographic projection of the third active portion on the base substrate.

2. The display panel according to claim 1, wherein the display panel comprises a plurality of pixel driving circuits distributed in an array along a row direction and a column direction, the auxiliary layer comprises a plurality of auxiliary units distributed in an array along the row direction and the column direction, an auxiliary unit is provided corresponding to a pixel driving circuit, and the second active portion comprises a third active sub-portion and a fourth active sub-portion;
wherein the auxiliary unit comprises:
a first auxiliary portion, an orthographic projection of the first auxiliary portion on the base substrate covering the orthographic projection of the third active portion on the base substrate; and
a second auxiliary portion, an orthographic projection of the second auxiliary portion on the base substrate covering an orthographic projection of the third active sub-portion on the base substrate and an orthographic projection of the fourth active sub-portion on the base substrate, respectively.

3. The display panel according to claim 2, wherein the active layer further comprises:
a tenth active portion, connected between the third active sub-portion and the fourth active sub-portion;
wherein the orthographic projection of the second auxiliary portion on the base substrate does not overlap with an orthographic projection of the tenth active portion on the base substrate.

4. The display panel according to claim 2, wherein the active layer further comprises:
a tenth active portion, connected between the third active sub-portion and the fourth active sub-portion;
wherein the second auxiliary portion comprises a first auxiliary sub-portion and a second auxiliary sub-portion, an orthographic projection of the first auxiliary sub-portion on the base substrate covers the orthographic projection of the third active sub-portion on the base substrate and the orthographic projection of the fourth active sub-portion on the base substrate, and an orthographic projection of the second auxiliary sub-portion on the base substrate covers an orthographic projection of the tenth active portion on the base substrate.

5. The display panel according to claim 4, wherein the display panel further comprises:
a second conductive layer, located on a side of the active layer away from the auxiliary layer, and comprising:
a first conductive block, an orthographic projection of the first conductive block on the base substrate being located on the orthographic projection of the tenth active portion on the base substrate;
a second source-drain metal layer, located on a side of the second conductive layer away from the base substrate, and comprising:
a first power line, an orthographic projection of the first power line on the base substrate extending along the column direction, and the first power line being coupled to the first conductive block through a third via hole;
wherein the orthographic projection of the second auxiliary sub-portion on the base substrate further covers an orthographic projection of the third via hole on the base substrate.

6. The display panel according to claim 1, wherein,
the active layer further comprises:
a first active portion, connected to a side of the second active portion, the first active portion being configured to form a channel region of the first transistor;
the auxiliary unit further comprises:
a fourth auxiliary portion, connected to the second auxiliary portion, an orthographic projection of the fourth auxiliary portion on the base substrate covering an orthographic projection of the first active portion on the base substrate;
the first active portion comprises a first active sub-portion and a second active sub-portion; and
the active layer further comprises:
a ninth active portion, connected between the first active sub-portion and the second active sub-portion;
wherein the orthographic projection of the fourth auxiliary portion on the base substrate further covers an orthographic projection of the ninth active portion on the base substrate.

7-8. (canceled)

9. The display panel according to claim 1, wherein the auxiliary unit further comprises:
a third connecting portion, connected between two auxiliary units adjacent in the column direction, and an orthographic projection of the third connecting portion on the base substrate extending along the column direction; and
a first connecting portion, connected to a side of the second auxiliary portion away from the first auxiliary portion in the column direction, wherein in two auxiliary units adjacent in the column direction, a third connecting portion of an auxiliary unit in a previous row is connected to a first connecting portion of an auxiliary unit in a next row, and an orthographic projection of the first connecting portion on the base substrate does not overlap with an orthographic projection of the first active portion on the base substrate;
wherein the first active portion comprises a first active sub-portion and a second active sub-portion;
the active layer further comprises:
a ninth active portion, connected between the first active sub-portion and the second active sub-portion;
wherein the orthographic projection of the first connecting portion on the base substrate does not overlap with an orthographic projection of the ninth active portion base substrate;
the pixel driving circuit further comprises a fourth transistor;
the active layer further comprises a fourth active portion, and the fourth active portion is configured to form a channel region of the fourth transistor; and
the auxiliary unit further comprises:
a third connecting portion, connected between two auxiliary units adjacent in the column direction, and an orthographic projection of the third connecting portion on the base substrate extending along the column direction; and
a sixth auxiliary portion, connected to the third connecting portion, and an orthographic projection of the sixth auxiliary portion on the base substrate extending along the row direction and covering an orthographic projection of the fourth active portion on the base substrate.

10-11. (canceled)

12. The display panel according to claim 1, wherein the pixel driving circuit further comprises a first transistor, and a second electrode of the first transistor is connected to the gate of the driving transistor;
the active layer further comprises:
a first active portion, connected to a side of the second active portion, the first active portion being configured to form a channel region of the first transistor;
the auxiliary unit further comprises:
a second connecting portion, respectively connected to the first auxiliary portion and the second auxiliary portion, an orthographic projection of the second connecting portion on the base substrate extending along the row direction, and two auxiliary units adjacent in the row direction being connected through the second connecting portion;
a third connecting portion, connected between two auxiliary units adjacent in the column direction, and an orthographic projection of the third connecting portion on the base substrate extending along the column direction; and
a first connecting portion or a fourth auxiliary portion, connected to a side of the second auxiliary portion in the column direction away from the first auxiliary portion, wherein in two auxiliary units adjacent in the column direction, a third connecting portion of an auxiliary unit in a previous row is connected to a first connecting portion or a fourth auxiliary portion of an auxiliary unit in a next row, an orthographic projection of the first connecting portion on the base substrate does not overlap with an orthographic projection of the first active portion on the base substrate, and an orthographic projection of the fourth auxiliary portion on the base substrate covers the orthographic projection of the first active portion on the base substrate.

13. The display panel according to claim 1, wherein the display panel further comprises:
at least one of a first source-drain metal layer or a second source-drain metal layer, located on a side of the active layer away from the base substrate, and comprising:
at least one of a second power line or a first power line, an orthographic projection of the at least one of the second power line or the first power line extending along the column direction, and in a non-display region of the display panel, the at least one of the second power line or the first power line being connected to the auxiliary layer through a via hole.

14. The display panel according to claim 1, wherein the display panel further comprises:
a second conductive layer, located on a side of the active layer away from the base substrate, and comprising:
a first initialization signal line, an orthographic projection of the first initialization signal line on the base substrate extending along the row direction; and
a second initialization signal line, an orthographic projection of the second initialization signal line on the base substrate extending along the row direction;
a first source-drain metal layer, located on a side of the second conductive layer away from the base substrate, and comprising at least one of:
a third initialization signal line, an orthographic projection of the third initialization signal line on the base substrate extending along the column direction, and the third initialization signal line being connected to the first initialization signal line through a first via hole; or
a fourth initialization signal line, an orthographic projection of the fourth initialization signal line on the base substrate extending along the column direction, and the fourth initialization signal line being connected to the second initialization signal line through a second via hole;
wherein the display panel comprises a first pixel column and a second pixel column that are sequentially and alternately distributed in the row direction; and
the orthographic projection of the third initialization signal line on the base substrate is at least partially located in a region where the second pixel column is located, the orthographic projection of the fourth initialization signal line on the base substrate is located in a region where the first pixel column is located, and both the first via hole and the second via hole are located in the first pixel column.

15. (canceled)

16. The display panel according to claim 3, wherein the pixel driving circuit further comprises a storage capacitor, a first electrode of the storage capacitor is connected to the gate of the driving transistor, and a second electrode of the storage capacitor is connected to a second power end; and
the display panel further comprises:
a first conductive layer, located on a side of the active layer away from the base substrate, and comprising:
a second conductive block, an orthographic projection of the second conductive block on the base substrate covering the orthographic projection of the third active portion on the base substrate, and the second conductive block being configured to form the first electrode of the storage capacitor;
a second conductive layer, located on a side of the first conductive layer away from the base substrate, and comprising:
a third conductive block, an orthographic projection of the third conductive block on the base substrate being located on the orthographic projection of the second conductive block on the base substrate, and the third conductive block being configured to form the second electrode of the storage capacitor; and
a first conductive block, an orthographic projection of the first conductive block on the base substrate being located on the orthographic projection of the tenth active portion on the base substrate;
a first source-drain metal layer, located on a side of the second conductive layer away from the base substrate, and comprising:
a first power transfer line, connected to the third conductive block respectively through a via hole, and further connected to a first conductive block in an adjacent pixel driving circuit through a via hole; and
a second power transfer line, connected to the third conductive block respectively through a via hole, and an extension length of an orthographic projection of the second power transfer line on the base substrate along the column direction being greater than an extension length of an orthographic projection of the first power transfer line on the base substrate along the column direction.

17. The display panel according to claim 16, wherein the first power transfer line comprises a first transfer portion, a second transfer portion and a third transfer portion, both an orthographic projection of the first transfer portion on the base substrate and an orthographic projection of the third transfer portion on the base substrate extend along the column direction, an orthographic projection of the second transfer portion on the base substrate extends along the row direction, and the first transfer portion and the third transfer portion are connected through the second transfer portion; and
the first transfer portion is connected to the third conductive block and the first power line respectively through a via hole, and the third transfer portion is located in another pixel driving circuit adjacent in the row direction and connected to the first conductive block through a via hole;
wherein the auxiliary unit further comprises:
a second connecting portion, connected to the first auxiliary portion and the second auxiliary portion respectively, an orthographic projection of the second connecting portion on the base substrate extending along the row direction, and two auxiliary units adjacent in the row direction being connected through the second connecting portion;
wherein an orthographic projection of the second transfer portion on the base substrate partially overlaps with an orthographic projection of the second connecting portion on the base substrate.

18. (canceled)

19. The display panel according to claim 17, wherein,
the first conductive layer further comprises:
a gate signal line, comprising a main extension portion and an additional portion, an orthographic projection of the main extension portion on the base substrate extending along the row direction and covering the orthographic projection of the third active sub-portion on the base substrate, an orthographic projection of the additional portion on the base substrate extending along the column direction and covering the orthographic projection of the fourth active sub-portion on the base substrate, and a partial structure of the gate signal line being configured to form a gate of the second transistor;
the second conductive layer further comprises:
a first initialization signal line, an orthographic projection of the first initialization signal line on the base substrate extending along the row direction;
the first source-drain metal layer further comprises:
a third initialization signal line, an orthographic projection of the third initialization signal line on the base substrate extending along the column direction, and the third initialization signal line being connected to the first initialization signal line through a via hole;
wherein, a first overlapping portion is provided between the orthographic projection of the third transfer portion on the base substrate and the orthographic projection of the main extension portion on the base substrate, a second overlapping portion is provided between the orthographic projection of the third initialization signal line on the base substrate and the orthographic projection of the additional portion on the base substrate, and the orthographic projection of the second auxiliary portion on the base substrate covers the first overlapping portion and the second overlapping portion.

20. The display panel according to claim 16, wherein the pixel driving circuit further comprises a fifth transistor, a gate of the fifth transistor is connected to an enable signal line, a first electrode of the fifth transistor is connected to a first power end, and a second electrode of the fifth transistor is connected to a second electrode of the driving transistor;
the active layer further comprises:
a fifth active portion, configured to form a channel region of the fifth transistor;
a sixteenth active portion, connected between the fifth active portion and the third active portion, and configured to form the second electrode of the fifth transistor and the second electrode of the driving transistor; and
a seventeenth active portion, connected to a side of the fifth active portion away from the sixteenth active portion, and configured to form the first electrode of the fifth transistor;
the first conductive layer further comprises:
an enable signal line, an orthographic projection of the enable signal line on the base substrate extending along the row direction and covering an orthographic projection of the fifth active portion on the base substrate, and a partial structure of the enable signal line being configured to form the gate of the fifth transistor;
wherein the seventeenth active portion is connected to the first power line through a via hole.

21. The display panel according to claim 20, wherein the pixel driving circuit further comprises a fourth transistor and a sixth transistor, a gate of the second transistor is connected to a gate signal end, and a second electrode of the second transistor is connected to the first electrode of the driving transistor, a gate of the fourth transistor is connected to a second reset signal end, a first electrode of the fourth transistor is connected to the second electrode of the driving transistor, a second electrode of the fourth transistor is connected to the second electrode of the fifth transistor, a gate of the sixth transistor is connected to the enable signal end, a first electrode of the sixth transistor is connected to the first electrode of the driving transistor, and a second electrode of the sixth transistor is connected to an anode of a light-emitting device;
the active layer further comprises:
a sixteenth active portion, connected to a side of the third active portion, and configured to form the second electrode of the driving transistor and the second electrode of the fifth transistor;
a fourteenth active portion, connected to a second bridge portion located in a first source-drain metal layer through a via hole, the second bridge portion being further connected to the sixteenth active portion through a via hole, and the fourteenth active portion being configured to form the first electrode of the fourth transistor;
a fourth active portion, connected to the fourteenth active portion, and configured to form a channel region of the fourth transistor;
a fifteenth active portion, connected to a side of the fourth active portion away from the fourteenth active portion, the fifteenth active portion being configured to form the second electrode of the fourth transistor;
a fifth active portion, configured to form a channel region of the fifth transistor;
a sixth active portion, configured to form a channel region of the sixth transistor;
a seventh active portion, configured to form a channel region of the seventh transistor;
the first conductive layer further comprises:
a first reset signal line, an orthographic projection of the first reset signal line on the base substrate covering an orthographic projection of the first active portion on the base substrate, and a partial structure of the first reset signal line being configured to form a gate of the first transistor;
a gate signal line, an orthographic projection of the gate signal line on the base substrate covering the orthographic projection of the second active portion on the base substrate, and a partial structure of the gate signal line being configured to form the gate of the second transistor;
an enable signal line, an orthographic projection of the enable signal line on the base substrate covering an orthographic projection of the fifth active portion on the base substrate and an orthographic projection of the sixth active portion on the base substrate, a partial structure of the enable signal line being configured to form the gate of the fifth transistor, and a partial structure of the enable signal line being configured to form the gate of the sixth transistor; and
a second reset signal line, an orthographic projection of the second reset signal line on the base substrate covering an orthographic projection of the fourth active portion on the base substrate and an orthographic projection of the seventh active portion on the base substrate, a partial structure of the second reset signal line being configured to form the gate of the fourth transistor, and a partial structure of the second reset signal line being configured to form a gate of the seventh transistor;
wherein the orthographic projection of the first reset signal line on the base substrate, the orthographic projection of the gate signal line on the base substrate, the orthographic projection of the enable signal line on the base substrate, and the orthographic projection of the second reset signal line on the base substrate all extend along the row direction and are sequentially distributed at intervals in the column direction; and the orthographic projection of the gate signal line on the base substrate and the orthographic projection of the enable signal line on the base substrate are located on either side of the orthographic projection of the third active portion on the base substrate.

22. A display panel, comprising a pixel driving circuit, wherein the pixel driving circuit comprises a second transistor and a driving transistor, a first electrode of the second transistor is connected to a gate of the driving transistor, and the display panel further comprises:
a base substrate, comprising an organic layer;
an auxiliary layer, located on a side of the base substrate;
an active layer, located on a side of the auxiliary layer away from the base substrate, and comprising:
a second active portion, configured to form a channel region of the second transistor; and
a third active portion, configured to form a channel region of the driving transistor;
wherein an orthographic projection of the auxiliary layer on the base substrate covers an orthographic projection of the second active portion on the base substrate and an orthographic projection of the third active portion on the base substrate.

23. The display panel according to claim 22, wherein the display panel comprises a plurality of pixel driving circuits distributed in an array along a row direction and a column direction, the auxiliary layer comprises a plurality of auxiliary units distributed in an array along the row direction and the column direction, an auxiliary unit is provided corresponding to a pixel driving circuit, and the second active portion comprises a third active sub-portion and a fourth active sub-portion;
the auxiliary unit comprises:
a first auxiliary portion, an orthographic projection of the first auxiliary portion on the base substrate covering the orthographic projection of the third active portion on the base substrate; and
a second auxiliary portion, an orthographic projection of the second auxiliary portion on the base substrate covering an orthographic projection of the third active sub-portion on the base substrate and an orthographic projection of the fourth active sub-portion on the base substrate respectively.

24. The display panel according to claim 23, wherein the pixel driving circuit further comprises a first transistor, and a second electrode of the first transistor is connected to the gate of the driving transistor;
the active layer further comprises:
a first active portion, connected to a side of the second active portion, and configured to form a channel region of the first transistor;
the auxiliary unit further comprises:
a second connecting portion, respectively connected to the first auxiliary portion and the second auxiliary portion, an orthographic projection of the second connecting portion on the base substrate extending along the row direction, and two auxiliary units adjacent in the row direction being connected through the second connecting portion; and
a fourth auxiliary portion, connected to the second auxiliary portion, an orthographic projection of the fourth auxiliary portion on the base substrate covering an orthographic projection of the first active portion on the base substrate.

25. A display apparatus, comprising a display panel, wherein the display panel comprises a pixel driving circuit, the pixel driving circuit comprises a second transistor and a driving transistor, a first electrode of the second transistor is connected to a gate of the driving transistor, and the display panel further comprises:
a base substrate;
an auxiliary layer, located on a side of the base substrate and connected to a first signal; and
an active layer, located on a side of the auxiliary layer away from the base substrate, and comprising:
a second active portion, configured to form a channel region of the second transistor; and
a third active portion, configured to form a channel region of the driving transistor;
wherein an orthographic projection of the auxiliary layer on the base substrate covers an orthographic projection of the second active portion on the base substrate and an orthographic projection of the third active portion on the base substrate.

26. A display apparatus, comprising the display panel according to claim 22.
